(19) United States
(12) Patent Application Publication
(10) Pub. No.: US 2025/0393406 A1
(43) Pub. Date: Dec. 25, 2025

(54) DISPLAY DEVICE, MANUFACTURING METHOD THEREOF AND ELECTRONIC DEVICE INCLUDING THE DISPLAY DEVICE

(71) Applicant: Samsung Display Co., Ltd., Yongin-si (KR)

(72) Inventors: Kye Uk LEE, Yongin-si (KR); Si Hyun AHN, Yongin-si (KR); Soo Hong CHEON, Yongin-si (KR)

(21) Appl. No.: 19/096,509

(22) Filed: Mar. 31, 2025

(30) Foreign Application Priority Data
Jun. 19, 2024 (KR) 10-2024-0079583
Aug. 5, 2024 (KR) 10-2024-0103859

(51) Int. Cl. H10K 59/122; H10K 59/35; H10K 59/88

(52) U.S. Cl. CPC H10K 59/122; H10K 59/353; H10K 59/88

(57) ABSTRACT

A display device includes a substrate; sub-pixels on the substrate; a via layer on the substrate and including a recessed pattern recessed in a direction toward the substrate; and a pixel defining layer defining an emission area and on the via layer in a non-emission area around the emission area. The pixel defining layer defines a light-emitting opening corresponding to the emission area and a dummy opening exposing a portion of the via layer in the non-emission area. In a plan view, the recessed pattern of the via layer and the dummy opening of the pixel defining layer overlap each other.

### CROSS-REFERENCE TO RELATED APPLICATION

The present application claims priority to and the benefit of Korean Patent Application Number 10-2024-0079583, filed on Jun. 19, 2024, and Korean Patent Application Number 10-2024-0103859, filed on Aug. 5, 2024, in the Korean Intellectual Property Office, the entire disclosures of all of which are incorporated herein by reference.

### BACKGROUND

### 1. Field

Embodiments of the present disclosure relate to a display device, a manufacturing method thereof, and an electronic device including the display device.

### 2. Description of the Related Art

Recently, as interest in information displays has increased, research and development on display devices are continuously being conducted.

### SUMMARY

Aspects of one or more embodiments of the present disclosure are directed to a display device with improved reliability and a manufacturing method thereof.

Additional aspects will be set forth in part in the description which follows and, in part, will be apparent from the description, or may be learned by practice of the presented embodiments of the disclosure.

A display device according to one or more embodiments includes: a substrate; sub-pixels on the substrate; a via layer arranged on the substrate and including (defining) a recessed pattern recessed in a direction toward the substrate; and a pixel defining layer defining an emission area and arranged on the via layer in a non-emission area positioned around the emission area. The pixel defining layer include (define) a light-emitting opening corresponding to the emission area and a dummy opening exposing a portion of the via layer in the non-emission area. In a plan view, the recessed pattern of the via layer and the dummy opening of the pixel defining layer intersect (overlap) each other.

In one or more embodiments, the sub-pixels may include a first sub-pixel emitting light of a first color, a second sub-pixel emitting light of a second color, and a third sub-pixel emitting light of a third color. The emission area may include a first emission area forming (defining) the first sub-pixel, a second emission area forming (defining) the second sub-pixel, and a third emission area forming (defining) the third sub-pixel.

In one or more embodiments, the dummy opening may include a first dummy opening extending in a first direction in the non-emission area between the first sub-pixel and the second sub-pixel and in the non-emission area between the second sub-pixel and the third sub-pixel; and a second dummy opening extending in a second direction intersecting the first direction in the non-emission area between the first sub-pixel and the third sub-pixel.

In one or more embodiments, the recessed pattern may include a first recessed pattern extending in the second direction and intersecting (overlapping) the first dummy opening; and a second recessed pattern extending in the first direction and intersecting (overlapping) the second dummy opening.

In one or more embodiments, the first dummy opening and the second dummy opening may be spaced and/or apart (e.g., spaced apart or separated).

The first dummy opening and the second dummy opening may be connected.

In one or more embodiments, first ends of the pixel defining layer at opposing sides of the pixel defining layer define the first dummy opening therebetween and may be arranged on the first recessed pattern. Second ends of the pixel defining layer at opposing sides of the pixel defining layer define the second dummy opening therebetween and may be arranged on the second recessed pattern.

In one or more embodiments, a boundary point between an upper surface of the via layer and the recessed pattern may be covered by the pixel defining layer.

In one or more embodiments, the first ends of the pixel defining layer may contact the first recessed pattern to define a first trench. The second ends of the pixel defining layer may contact the second recessed pattern to define a second trench.

In one or more embodiments, the display device may further include an anode electrode arranged between the via layer of each of the sub-pixels and the pixel defining layer and exposed by the light-emitting opening of the pixel defining layer; an emission structure arranged on the anode electrode and the pixel defining layer; and a cathode electrode arranged on the emission structure.

In one or more embodiments, the emission structure may include a first emission unit arranged on the anode electrode and the pixel defining layer and to emit light; an intermediate layer arranged on the first emission unit; and a second emission unit arranged on the intermediate layer and to emit light. The first emission unit and the intermediate layer may be disconnected at (in) each of the first and second trenches, and the second emission unit may not be disconnected on the first and second trenches.

In one or more embodiments, the first trench may include (define) a first void surrounded by (defined by) the first recessed pattern, the first ends of of the pixel defining layer, the first emission unit, the intermediate layer, and the second emission unit. The second trench may include (define) a second void defined by the second recessed pattern, the second ends of the pixel defining layer, the first emission unit, the intermediate layer, and the second emission unit.

In one or more embodiments, the first recessed pattern may include a plurality of first recessed patterns arranged along the first direction. The second recessed pattern may include a plurality of second recessed patterns arranged along the second direction.

In one or more embodiments, each of the plurality of first recessed patterns may intersect (overlap) the first dummy opening. Each of the plurality of second recessed patterns may intersect (overlap) the second dummy opening.

In one or more embodiments, the first dummy opening may include a plurality of first sub-dummy openings which are spaced and/or apart (e.g., spaced apart or separated) from each other. At least one of the plurality of first sub-dummy openings may intersect (overlap) one of the first recessed patterns.

In one or more embodiments, the dummy opening may include a first dummy opening extending in a first direction in the non-emission area between the first sub-pixel and the second sub-pixel and in the non-emission area between the second sub-pixel and the third sub-pixel; and a second dummy opening extending in the first direction in the non-emission area between the first sub-pixel and the third sub-pixel. The second dummy opening may include a plurality of second sub-dummy openings extending in the first direction and arranged along a second direction intersecting the first direction.

In one or more embodiments, the recessed pattern may include a first recessed pattern extending in the second direction and intersecting (overlapping) the first dummy opening; and a second recessed pattern extending in the second direction and intersecting (overlapping) the plurality of second sub-dummy openings. The second recessed pattern may be provided in the form of a line (e.g., may have the shape of a line).

In one or more embodiments, the dummy opening may include a first dummy opening extending in a second direction in the non-emission area between the first sub-pixel and the second sub-pixel; and a second dummy opening extending in the second direction in the non-emission area between the second sub-pixel and the third sub-pixel. The recessed pattern may extend in a first direction intersecting the second direction and may intersect (overlap) each of the first and second dummy openings.

A display device according to one or more embodiments includes a substrate; a first sub-pixel, a second sub-pixel, and a third sub-pixel on the substrate; a via layer arranged on the substrate and including (defining) a recessed pattern recessed in a direction toward the substrate; and a pixel defining layer on the via layer in a non-emission area and defining a first emission area of the first sub-pixel, a second emission area of the second sub-pixel, and a third emission area of the third sub-pixel. The pixel defining layer includes (defines) a first opening corresponding to the first emission area, a second opening corresponding to the second emission area, a third opening corresponding to the third emission area, and a dummy opening exposing a portion of the via layer in the non-emission area. In a plan view, the recessed pattern of the via layer and the dummy opening of the pixel defining layer intersect (overlap) each other.

In one or more embodiments of the present disclosure, a method of manufacturing a display device having sub-pixels including a emission area includes: forming, on a substrate, a via layer including a recessed pattern recessed in a direction toward the substrate; forming a pixel defining layer defining the emission area on the via layer in a non-emission area around the emission area; and forming an emission structure on the pixel defining layer. The pixel defining layer includes (defines) a light-emitting opening corresponding to the emission area and a dummy opening exposing a portion of the via layer in the non-emission area. In a plan view, the recessed pattern of the via layer and the dummy opening of the pixel defining layer intersect (overlap) each other.

An electronic device according to one or more embodiments includes a display device including a substrate; sub-pixels on the substrate; a via layer on the substrate and defining a recessed pattern recessed in a direction toward the substrate; and a pixel defining layer defining an emission area and on the via layer in a non-emission area around the emission area. The pixel defining layer defines a light-emitting opening corresponding to the emission area and a dummy opening exposing a portion of the via layer in the non-emission area. In a plan view, the recessed pattern of the via layer and the dummy opening of the pixel defining layer overlap each other.

According to one or more embodiments, in an area of a non-emission area between sub-pixels, an intermediate layer (or a charge generating layer) may be disconnected at (on) a trench formed by intersection (the overlapping) of a recessed pattern (or a groove) of a via layer and a dummy opening of a pixel defining layer. Accordingly, current outflowing through the intermediate layer to adjacent sub-pixels may be reduced or prevented, thereby improving reliability of a display device.

Effects according to one or more embodiments are not limited to those above, and more diverse effects may be included in the present specification.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a schematic plan view illustrating a display device according to one or more embodiments of the present disclosure.

FIG. 2 is a schematic block diagram illustrating the display device of FIG. 1, according to one or more embodiments of the present disclosure.

FIG. 3 is a circuit diagram schematically illustrating an electrical connection of components included in a sub-pixel of FIG. 1, according to one or more embodiments of the present disclosure.

FIG. 4A is a schematic plan view illustrating one of the pixels of FIG. 1, according to one or more embodiments of the present disclosure.

FIG. 4B is a schematic plan view illustrating one of the pixels of FIG. 1, according to one or more embodiments of the present disclosure.

FIG. 4C is a schematic plan view illustrating one of the pixels of FIG. 1, according to one or more embodiments of the present disclosure.

FIG. 5 is a schematic cross-sectional diagram taken along the line I-I′ of FIG. 4A, according to one or more embodiments of the present disclosure.

FIG. 6 is a schematic cross-sectional diagram illustrating an emission structure included in one of first to third light-emitting elements of FIG. 5, according to one or more embodiments of the present disclosure.

FIG. 7 is a schematic plan view illustrating an area of a display area of FIG. 1, according to one or more embodiments of the present disclosure.

FIG. 8 is a schematic cross-sectional diagram taken along the line II-II′ of FIG. 7, according to one or more embodiments of the present disclosure.

FIG. 9 is an enlarged schematic cross-sectional diagram of an area EA of FIG. 8, according to one or more embodiments of the present disclosure.

FIG. 10 is a schematic perspective view illustrating a via layer and a pixel defining layer of FIG. 7, according to one or more embodiments of the present disclosure.

FIG. 11-FIG. 15 are schematic cross-sectional diagrams (views) taken along the line II-II′ of FIG. 7, illustrating a manufacturing method of a display device according to one or more embodiments of the present disclosure.

FIG. 16-FIG. 18 are each a schematic plan view illustrating an area of a display area of a display device, according to one or more embodiments of the present disclosure.

FIG. 19 is a schematic plan view illustrating an area of a display area of a display device, according to one or more embodiments of the present disclosure.

FIG. 20 is a block diagram of an electronic device according to one or more embodiments of the present disclosure.

FIG. 21 shows schematic views of various embodiments of an electronic device.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

The terminology used herein is for the purpose of describing particular embodiments only and is not intended to be limiting of the present disclosure. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof. As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Various embodiments are described with reference to drawings illustrating example embodiments. Accordingly, it is to be expected, for example, that shapes may change depending on tolerances and/or manufacturing techniques. Thus, embodiments disclosed herein may not be construed as being limited to the specific shapes depicted, but should be construed as including variations of the shapes resulting from, for example, manufacturing. As such, the shapes shown in the drawings may not show actual shapes of areas of the device, and the present embodiments are not limited thereto. In addition, in the drawings, the relative sizes of elements, layers, and regions may be exaggerated for clarity.

Unless otherwise noted, like reference numerals denote like elements throughout the attached drawings and the written description, and thus, duplicative descriptions thereof may not be provided. As used herein, the singular forms “a,” “an” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction (DR1) and the second direction (DR2). This refers to that in a plan view, the arrangement of sub-pixels, pads, and other components as they are laid out on the substrate can be seen, without any perspective distortion.

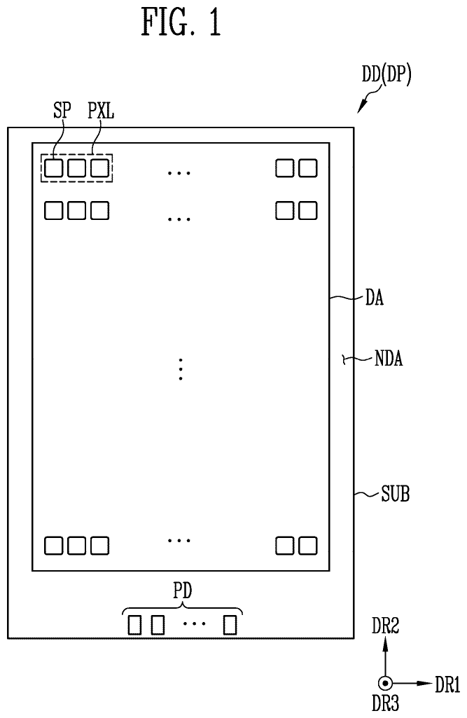

FIG. 1 is a schematic plan view illustrating a display device DD according to one or more embodiments of the present disclosure. For convenience, FIG. 1 briefly illustrates a structure of the display device DD, for example, a display panel DP provided in the display device DD, centered on a display area DA where an image is displayed.

Referring to FIG. 1, the display device DD (or the display panel DP) may include the display area DA and a non-display area NDA. The display panel DP may display images through the display area DA. The non-display area NDA may be arranged around the display area DA.

The display panel DP may include a substrate SUB, sub-pixels SP, and pads PD.

The substrate SUB may include a transparent insulating material to allow light to pass through. The substrate SUB may be a rigid or a flexible substrate.

The rigid substrate may, for example, be one of a glass substrate, a quartz substrate, a glass-ceramic substrate, and/or a crystalline glass substrate.

The flexible substrate may be one of a film substrate including a polymeric organic material or a plastic substrate. For example, the flexible substrate may include at least any one of polystyrene, polyvinyl alcohol, polymethyl methacrylate, polyether sulfone, polyacrylate, polyetherimide, polyethylene naphthalate, polyethylene terephthalate, polyphenylene sulfide, polyacrylate, polyimide, polycarbonate, triacetate cellulose, and/or cellulose acetate propionate.

One area on the substrate SUB may be provided as the display area DA where the sub-pixels SP (or pixels PXL) are arranged, and the remaining area on the substrate SUB may be provided as the non-display area NDA. For example, the substrate SUB may include the display area DA including the pixel areas in which each sub-pixel SP (or each pixel PXL) is arranged, and the non-display area NDA arranged around the display area DA) (or adjacent to the display area DA).

The display area DA may have a variety of shapes. For example, the display area DA may be provided in a variety of shapes, such as a closed polygon including sides consisting of straight lines, a circle or ellipse including a side consisting of curves, or a semicircle or semi-ellipse including sides consisting of straight lines and curves.

The non-display area NDA may be provided on at least one side of the display area DA. For instance, the non-display area NDA may enclose the perimeter of the display area DA. The sub-pixels SP may be arranged in the form of matrix along a first direction DR1 and a second direction DR2 intersecting the first direction DR1 on the substrate SUB, but the arrangement of the sub-pixels SP is not limited thereto. For example, the sub-pixels SP may be arranged in a zigzag form along the first direction DR1 and the second direction DR2. For example, the first direction DR1 may be a row direction, and the second direction DR2 may be a column direction.

Two or more sub-pixels SP out of a plurality of sub-pixels SP may constitute a single pixel PXL, but the present disclosure is not limited to.

In the non-display area NDA on the substrate SUB, a component for controlling the sub-pixels SP may be arranged. For example, wirings electrically connected to the sub-pixels SP may be arranged in the non-display area NDA. The wirings may include, for example, gate lines and data lines.

In order to drive the sub-pixels SP in the non-display area NDA of the display panel DP, a driver electrically connected to the sub-pixels SP may be arranged (or integrated). The pads PD may be arranged in the non-display area NDA on the substrate SUB. The pads PD may be electrically connected to the sub-pixels SP through wiring. For example, the pads PD may be electrically connected to sub-pixels SP through the data lines.

In one or more embodiments, a circuit board may be electrically connected to the pads PD by a conductive adhesive member, such as anisotropic conductive films. The circuit board may be a flexible circuit board or a flexible film with a flexible material. The driver may be mounted on the circuit board and electrically connected to the pads PD.

In one or more embodiments, the display panel DP may have a flat display surface. According to one or more embodiments, the display panel DP may have at least a partially rounded display surface. In one or more embodiments, the display panel DP may be bendable, foldable, or rollable. In such embodiments, the display panel DP and/or the substrate SUB may include materials having flexible properties.

The display device DD according to one or more embodiments of the present disclosure may be applied to portable electronic devices such as mobile phones, smartphones, tablet personal computers (PCs), mobile communication terminals, electronic notebooks, electronic books, portable multimedia players (PMPs), navigation devices, and/or ultra-mobile PCs (UMPCs). Alternatively, the display device 10 according to one or more embodiments may be applied as a display unit of a television, a notebook computer, a monitor, a billboard, and/or an Internet of things (IoT) device. Alternatively, the display device 10 according to one or more embodiments may be applied to wearable devices such as smart watches, watch phones, glasses-type (kind) displays, and/or head-mounted displays (HMDs). Alternatively, the display device 10 according to one or more embodiments may be applied to a car display, such as a display in a dashboard of a vehicle, a center fascia of a vehicle, a center information display (CID) arranged on a dashboard of a vehicle, a room mirror display replacing side mirrors of a vehicle, and/or a display arranged on the back of a front seat as an entertainment for rear-seat passengers of a vehicle.

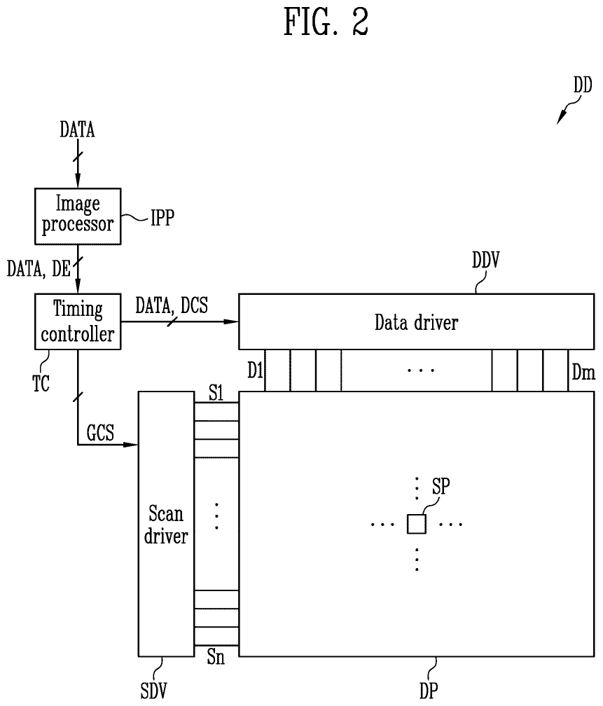

FIG. 2 is a schematic block diagram illustrating a display device DD of FIG. 1, according to one or more embodiments of the present disclosure.

Referring to FIG. 1 and FIG. 2, the display device DD according to one or more embodiments may include the display panel DP, the driver, and a wiring unit.

The display panel DP may display images in response to data signals DATA and scan signals supplied from a data driver DDV and a scan driver SDV. The display panel DP may include a plurality of sub-pixels SP that display images.

The driver may include an image processor IPP, a timing controller TC, the data driver DDV, and the scan driver SDV.

The image processor IPP may output data enabling signals DE as well as data signals DATA that are externally supplied. In addition to the data enabling signals DE, the image processor IPP may output one or more of vertical synchronous signals, horizontal synchronous signals, and/or clock signals.

The timing controller TC may receive, from the image processor IPP, data enabling signals DE or driving signals and data signals DATA, including vertical synchronous signals, horizontal synchronous signals, and/or clock signals. The timing controller TC may output gate control signals GCS to control the operation timing of the scan driver SDV and a data control signal DCS to control the operation timing of the data driver DDV based on the driving signal.

The data driver DDV responds to the data control signal DCS supplied from the timing controller TC to output the data signal DATA supplied from the timing controller TC by converting it into a corresponding data voltage. The data driver DDV may supply the data voltage to data lines D1-Dm. The data voltage supplied to the data lines D1-Dm may be supplied to the sub-pixels SP selected by the scan signal.

The scan driver SDV may apply the scan signal to the scan lines S1-Sn in response to the gate control signal GCS supplied from the timing controller TC. For example, the scan driver SDV may allow the sub-pixels SP to be sequentially selected in a unit of horizontal lines once the scan signal is supplied sequentially to the scan lines S1-Sn.

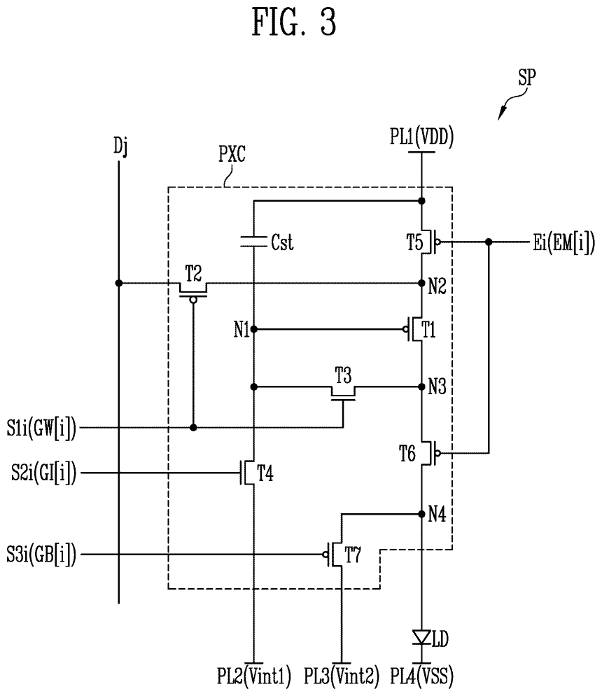

FIG. 3 is a circuit diagram schematically illustrating an electrical connection of components included in the sub-pixel SP of FIG. 1, according to one or more embodiments of the present disclosure. For convenience of explanation, the sub-pixel shown in FIG. 3 is the sub-pixel SP that is positioned in an i-th horizontal line (or an i-th pixel row) and connected to a j-th data line Dj.

Referring to FIG. 1 to FIG. 3, the sub-pixel SP may be arranged in the i-th horizontal line (or the i-th pixel row). The sub-pixel SP may include a pixel circuit PXC and a light-emitting element LD. The pixel circuit PXC may include first, second, third, fourth, fifth, sixth, and seventh transistors T1, T2, T3, T4, T5, T6, T7 and a storage capacitor Cst.

A first electrode of the light-emitting element LD may be electrically connected to a fourth node N4, and a second electrode of the light-emitting element LD may be electrically connected to a fourth power wiring PL4. The light-emitting element LD may generate light of a certain brightness in response to the amount of current (or drive current) supplied from the first transistor T1. In one or more embodiments, the light-emitting element LD may be an organic light-emitting diode including an organic light-emitting layer.

The first transistor T1 (or a drive transistor) may be electrically connected between a first power wiring PL1 and a first electrode of the light-emitting element LD. The first transistor T1 may include a gate electrode that is electrically connected to a first node N1. The first transistor T1 may control the amount of current (or drive current) flowing from the first power wiring PL1 to the fourth power wiring PL4 by passing through the light-emitting element LD based on the voltage of the first node N1. A first power voltage VDD may be applied to the first power wiring PL1, a second power voltage VSS may be applied to the fourth power wiring PL4, and the first power voltage VDD may be set to a voltage that is higher than that of the second power voltage VSS.

The second transistor T2 may be electrically connected between the j-th data line Dj and a second node N2. The gate electrode of the second transistor T2 may be connected to the i-th first scan line Sli (or a first scan line). The second transistor T2 may be turned on when a first scan signal GW[i] (e.g., a low-level first scan signal) is supplied to the i-th first scan line S1i to electrically connect the second node N2 to the j-th data line Dj. When the first transistor T1 and the third transistor T3 are each in a turn-on state, the second transistor T2 may forward the data signal from the j-th data line Dj to the second node N2 in response to the first scan signal GW[i].

The third transistor T3 may be electrically connected between the first node N1 and a third node N3. The gate electrode of the third transistor T3 may be electrically connected to the i-th first scan line S1i. The third transistor T3 may be turned on when the first scan signal GW[i] is supplied to the i-th first scan line S1i. When the third transistor T3 is turned on, the first transistor T1 may have a diode-connected form.

The fourth transistor T4 may be electrically connected between the first node N1 and a second power wiring PL2. The gate electrode of the fourth transistor T4 may be electrically connected to a i-th second scan line S2i (or a second scan line). A first initialization power voltage Vint1 may be applied to the second power wiring PL2. The fourth transistor T4 may be turned on by a second scan signal GI[i] supplied to the i-th second scan line S2i. When the fourth transistor T4 is turned on, the first initialization power voltage Vint1 may be supplied to the first node N1 (i.e., the gate electrode of the first transistor T1).

The fifth transistor T5 may be electrically connected between the first power wiring PL1 and the second node N2. The gate electrode of the fifth transistor T5 may be electrically connected to the i-th light-emitting control line Ei (or a light-emitting control line). The sixth transistor T6 may be electrically connected between the third node N3 and the light-emitting element LD (or the fourth node N4). The gate electrode of the sixth transistor T6 may be electrically connected to the i-th light-emitting control line Ei. The fifth transistor T5 and the sixth transistor T6 may be turned off when a light-emitting control signal EM[i] (e.g., a high-level light-emitting control signal EM[i]) is supplied to the i-th light-emitting control line Ei and turned on.

The seventh transistor T7 may be electrically connected between the first electrode (i.e., the fourth node N4) of the light-emitting element LD and a third power wiring PL3. The gate electrode of the seventh transistor T7 may be electrically connected to an i-th third scan line S3i. A second initialization power voltage Vint2 may be applied to the third power wiring PL3. According to one or more embodiments, the second initialization power voltage Vint2 may be the same or different from the first initialization power voltage Vint1. The seventh transistor T7 may be turned on by a third scan signal GB[i] supplied to the i-th third scan line S3i to supply a second initialization power voltage Vint2 to the first electrode of the light-emitting element LD.

The storage capacitor Cst may be connected or formed between the first power wiring PL1 and the first node N1.

In one or more embodiments, the pixel circuit PXC may include a P-type (kind) transistor and/or an N-type (kind) transistor. The third transistor T3 and fourth transistor T4 may each be formed as an oxide semiconductor transistor including one or more oxide semiconductors. For example, the third transistor T3 and fourth transistor T4 may each be an N-type (kind) oxide semiconductor transistor and may include an oxide semiconductor layer as an active layer, but the present disclosure is not limited thereto. The oxide semiconductor transistor may be processed at low temperatures and may have a lower charge mobility than polysilicon semiconductor transistors. For example, oxide semiconductor transistors exhibit excellent or suitable off-current characteristics. Thus, the leakage current in the third transistor T3 and fourth transistor T4 may be minimized or reduced.

The remaining transistors (e.g., first, second, fifth, sixth, and seventh transistors T1, T2, T5, T6, T7) may be formed as polysilicon transistors including silicon semiconductors and each may include a polysilicon semiconductor layer as the active layer. For example, the active layer may be formed through a low-temperature polysilicon process (e.g., a low-temperature poly-silicon (LTPS) process). For example, a polysilicon transistor may be a P-type (kind) polysilicon transistor. The polysilicon semiconductor transistor may have a fast response rate, such that it may be applied to switching elements where fast switching is desired or required.

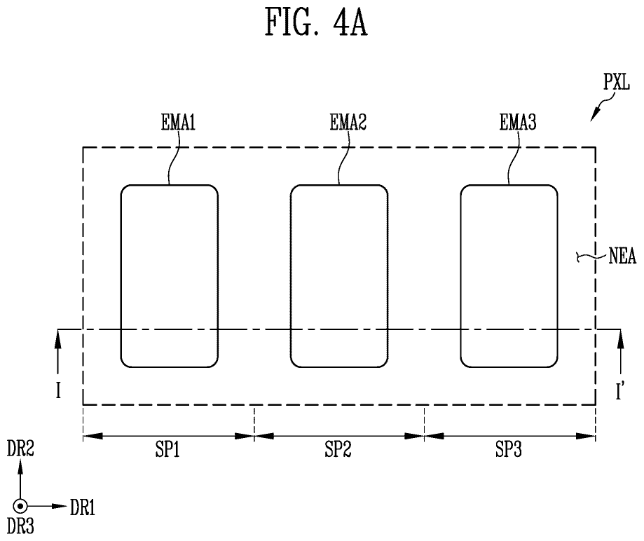

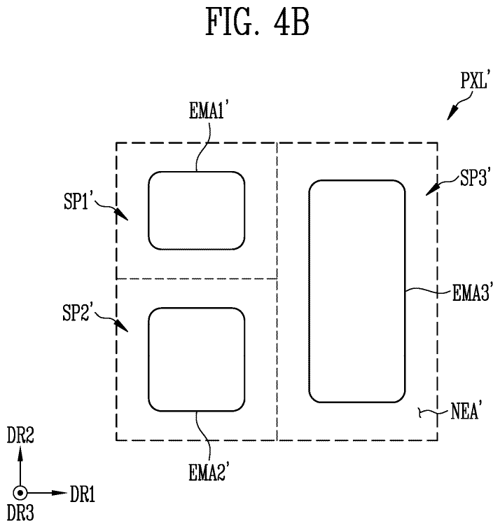

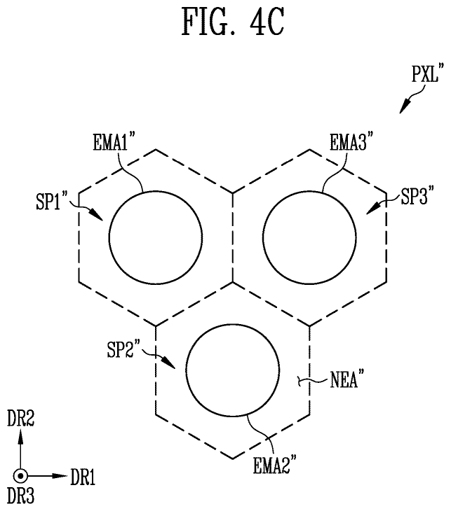

FIG. 4A is a schematic plan view illustrating one of the pixels PXL of FIG. 1, according to one or more embodiments of the present disclosure.

Referring to FIG. 1 and FIG. 4A, the pixel PXL may include a first sub-pixel SP1, a second sub-pixel SP2, and a third sub-pixel SP3 that are arranged in the first direction DR1.

The first sub-pixel SP1 may include a first emission area EMA1 and a non-emission area NEA around the first emission area EMA1. The second sub-pixel SP2 may include a second emission area EMA2 and the non-emission area NEA around the second emission area EMA2. The third sub-pixel SP3 may include a third light-emitting area EMA3 and the non-emission area NEA around the third emission area EMA3.

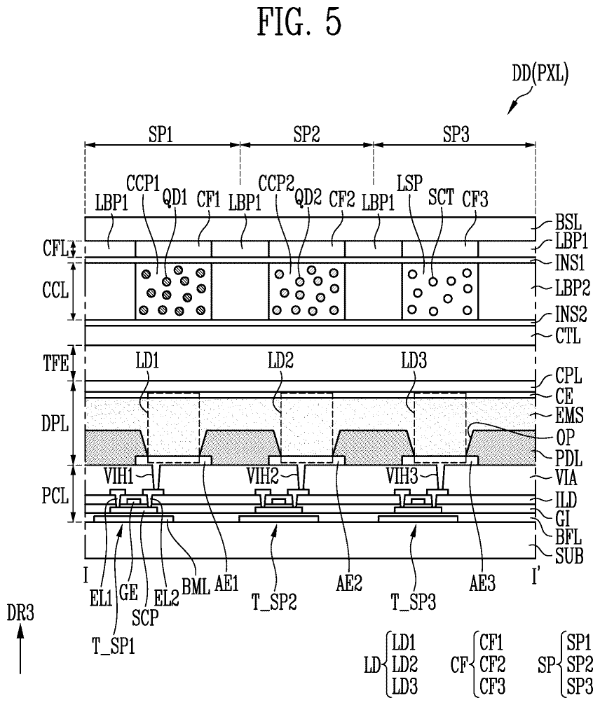

The first emission area EMA1 may be an area where light is emitted from a portion of an emission structure (see, e.g., “EMS” in FIG. 5) corresponding to the first sub-pixel SP1. The second emission area EMA2 may be an area where light is emitted from a portion of the emission structure EMS corresponding to the second sub-pixel SP2. The third emission area EMA3 may be an area where light is emitted from a portion of the emission structure EMS corresponding to the third sub-pixel SP3.

FIG. 4B is a schematic plan view illustrating one of the pixels PXL of FIG. 1, according to one or more embodiments of the present disclosure.

Referring to FIG. 1 and FIG. 4B, pixels PXL′ may include a first sub-pixel SP1′, a second sub-pixel SP2′, and a third sub-pixel SP3′.

The first sub-pixel SP1′ may include a first emission area EMA1′ and a non-emission area NEA′ around the first emission area EMA1′. The second sub-pixel SP2′ may include a second emission area EMA2′ and the non-emission area NEA′ around the second emission area EMA2′. The third sub-pixel SP3′ may include a third emission area EMA3′ and the non-emission area NEA′ around the third emission area EMA3′.

The first to third sub-pixels SP1′ to SP3′ may have, but are not limited thereto, square shapes when viewed in a third direction DR3 (e.g. in a plan view).

The first sub-pixel SP1′ and the second sub-pixel SP2′ may be arranged in the second direction DR2. The third sub-pixel SP3′ may be arranged in the first direction DR1 relative to each of the first and second sub-pixels SP1′ and SP2′.

The second sub-pixel SP2′ may have an area greater than the first sub-pixel SP1′, and the third sub-pixel SP3′ may have an area greater than the second sub-pixel SP2′. Accordingly, the second emission area EMA2′ may have an area greater than the first emission area EMA1′, and the third emission area EMA3′ may have an area greater than the second emission area EMA2′. However, the present disclosure is not limited thereto. For example, the first and second sub-pixels SP1′ and SP2′ may have substantially the same area as each other, and the third sub-pixel SP3′ may have an area greater than each of the first and second sub-pixels SP1′ and SP2′. As such, the areas of the first to third sub-pixels SP1′ to SP3′ may be diversely modified according to one or more embodiments.

FIG. 4C is a schematic plan view illustrating one of the pixels PXL of FIG. 1, according to one or more embodiments of the present disclosure.

Referring to FIG. 1 and FIG. 4C, a first sub-pixel SP1″ may include a first emission area EMA1″ and a non-emission area NEA″ around the first emission area EMA1″. A second sub-pixel SP2″ may include a second emission area EMA2″ and the non-emission area NEA″ around a second emission area EMA2″. A third sub-pixel SP3″ may include a third emission area EMA3″ and the non-emission area NEA″ around the third emission area EMA3″.

The first to third sub-pixels SP1″ to SP3″ may have polygonal shapes when viewed in the third direction DR3 (e.g. in a plan view). For example, the shapes of the first to third sub-pixels SP1″ to SP3″ may be hexagons, as shown in FIG. 4C.

The first to third emission areas EMA1″ to EMA3″ may have circular shapes when viewed in the third direction DR3 (e.g. in a plan view). However, the present disclosure is not limited thereto. For example, each of the first to third emission areas EMA1″ to EMA3″ may have polygonal shapes.

The first and third sub-pixels SP1″, SP3″ may be arranged in the first direction DR1. The second sub-pixel SP2″ may be arranged, relative to the first sub-pixel SP1″, in an inclined direction (or diagonally) at an acute angle based on the second direction DR2.

The arrangements of the sub-pixels shown in FIG. 4A, FIG. 4B, and FIG. 4C are examples, and the present disclosure is not limited thereto. Each pixel may include two or more sub-pixels, the sub-pixels may be arranged in one or more suitable ways, each of the sub-pixels may have a variety of shapes, and each of its emission areas may also have a variety of shapes.

FIG. 5 is a schematic cross-sectional diagram taken along the line I-I′ of FIG. 4A, according to one or more embodiments of the present disclosure.

In FIG. 5, for the convenience in explanation, the cross-sectional structure (or a stacked structure) of the display device DD is briefly shown centered on the pixel PXL formed on the substrate SUB, and a thickness direction of the substrate SUB is indicated as the third direction DR3.

Referring to FIG. 1, FIG. 4A, and FIG. 5, the display device DD may include at least one or more pixels PXL arranged in the display area DA of the substrate SUB.

The pixel PXL may include at least one sub-pixel. For example, the pixel PXL may include the first sub-pixel SP1, the second sub-pixel SP2, and the third sub-pixel SP3. In one or more embodiments, the first sub-pixel SP1 may be a red sub-pixel, the second sub-pixel SP2 may be a green sub-pixel, and the third sub-pixel SP3 may be a blue sub-pixel.

Each of first, second, and third sub-pixels SP1, SP2, and SP3 may include the substrate SUB, a pixel circuit layer PCL, a display element layer DPL, and a thin film encapsulation layer TFE.

The substrate SUB may include transparent insulating materials to allow light to pass through. The substrate SUB may be a rigid substrate or a flexible substrate.

The pixel circuit layer PCL and the display element layer DPL may be arranged to overlap each other on one side of the substrate SUB.

At least one insulation layer may be arranged in the pixel circuit layer PCL. For example, the insulation layer may include a buffer layer BFL, a gate insulation layer GI, an interlayer insulation layer ILD, and/or a via layer VIA that are sequentially stacked on the substrate SUB along the third direction DR3. The insulation layer arranged in the pixel circuit layer PCL is not limited to embodiments described above, and other insulation layers may be added.

The buffer layer BFL may be arranged over the whole area on the substrate SUB. The buffer layer BFL may prevent or reduce the diffusion of impurities into the circuit elements (e.g., transistors) that make up the pixel circuit PXC. The buffer layer BFL may be an inorganic insulation film including an inorganic material. The buffer layer BFL may include at least one of silicon nitride (SiₓN_{y}, where, e.g., 0<x≤3 and 0<y≤4), silicon oxide (SiOₓ, where, e.g., 0<x≤2), silicon oxynitride (SiOₓN_{y}, where, e.g., 0<x≤2 and 0<y≤4), and/or aluminum oxide (AlₓO_{y}, where, e.g., 0<x≤2 and 0<y≤3). The buffer layer BFL may be provided as a single film, but may also be provided as a multilayer with at least two or more films. If the buffer layer BFL is provided as a multilayer, each layer may be formed of the same material or a different material. In one or more embodiments, the buffer layer BFL may not be provided depending on the materials and processing conditions of the substrate SUB.

The gate insulation layer GI may be arranged over the whole area on the buffer layer BFL. The gate insulation layer GI may include the same material as the buffer layer BFL described above, or it may include a suitable (or selected) material from the materials listed above as a component of the buffer layer BFL. For example, the gate insulation layer GI may be an inorganic insulation film including an inorganic material.

The interlayer insulation layer ILD may be provided and/or formed over the whole area on the gate insulation layer GI. The interlayer insulation layer ILD may include the same material as the buffer layer BFL, or it may include one or more suitable (or selected) materials from the materials listed above as a component of the buffer layer BFL.

The via layer VIA may be provided and/or formed over the whole area on the interlayer insulation layer ILD. The via layer VIA may be an inorganic insulation film including an inorganic material or an organic insulation film including an organic material. The inorganic insulation films may include, for example, at least one of silicon oxide, silicon nitride, silicon oxynitride, and/or aluminum oxide. The organic insulation film may include, for example, at least one of acrylic resins, epoxy-based resins, phenolic resins, polyamide-based resins, polyimide-based resins, unsaturated polyester-based resins, polyphenylene ether-based resins, polyphenylene sulfide-based resins, and/or benzocyclobutene resins. In one or more embodiments, the via layer VIA may be an organic insulation film including an organic material.

The via layer VIA may be partially opened to include a via hole. The via hole may be a connection point for electrically connecting the pixel circuit PXC of each sub-pixel and the light-emitting element LD.

In the pixel circuit layer PCL, circuit elements of each of the first to third sub-pixels SP1 to SP3 may be arranged. For example, a transistor T_SP1 of the first sub-pixel SP1, a transistor T_SP2 of the second sub-pixel SP2, and a transistor T_SP3 of the third sub-pixel SP3 may be arranged in the pixel circuit layer PCL. The transistor T_SP1 of the first sub-pixel SP1 may be one of the transistors included in the pixel circuit PXC of the first sub-pixel SP1, the transistor T_SP2 of the second sub-pixel SP2 may be one of the transistors included in the pixel circuit PXC of the second sub-pixel SP2, and the transistor T_SP3 of the third sub-pixel SP3 may be one of the transistors included in the pixel circuit PXC of the third sub-pixel SP3. In FIG. 5, one of the transistors of each sub-pixel is shown for clarity and conciseness of explanation, and the remaining circuit elements are not provided in FIG. 5.

The transistor T_SP1 of the first sub-pixel SP1 may include a semiconductor pattern SCP, the gate electrode GE, a first terminal EL1, and a second terminal EL2.

The gate electrode GE may be arranged on the gate insulation layer GI to be covered by the interlayer insulation layer ILD. For example, the gate electrode GE may be a gate conductive layer that is positioned between the gate insulation layer GI and the interlayer insulation layer ILD. The gate electrode GE may overlap a portion of the semiconductor pattern SCP. For example, the gate electrode GE may overlap with the active layer of the semiconductor pattern SCP.

The semiconductor pattern SCP may be provided and/or formed on the buffer layer BFL. The semiconductor pattern SCP may be a semiconductor layer including (e.g., consisting of) polysilicon, amorphous silicon, oxide semiconductors, and/or the like. The semiconductor pattern SCP may include an active layer, a first contact area, and a second contact area. The active layer, the first contact area, and the second contact area may include semiconductor layers which are not doped with impurities or are doped with impurities. For example, the first contact area and the second contact area may include semiconductor layers doped with impurities, and the active layer may include a semiconductor layer undoped with impurities.

The active layer of the semiconductor pattern SCP is an area that overlaps the gate electrode GE, which may be a channel area. The first contact area of the semiconductor pattern SCP may contact one end of the active layer. The first contact area may be electrically connected to the first terminal EL1. The second contact area of the semiconductor pattern SCP may contact the other end of the active layer. The second contact area may be electrically connected to the second terminal EL2.

The first terminal EL1 may be provided and/or formed on an interlayer insulation layer ILD. For example, the first terminal EL1 may be formed of a source-drain conductive layer formed between the interlayer insulation layer ILD and the via layer VIA. The first terminal EL1 may contact the first contact area of the semiconductor pattern SCP through a contact hole that penetrates the gate insulation layer GI and the interlayer insulation layer ILD.

The second terminal EL2 may be provided and/or formed on the interlayer insulation layer ILD and arranged to be spaced and/or apart (e.g., spaced apart or separated) from the first terminal EL1. The second terminal EL2 may be formed of the source-drain conductive layer formed between the interlayer insulation layer ILD and the via layer VIA. The second terminal EL2 may contact the second contact area of the semiconductor pattern SCP through another contact hole that penetrates the gate insulation layer GI and the interlayer insulation layer ILD.

According to one or more embodiments, a lower metal layer BML may be arranged on the bottom of the transistor T_SP1 of the first sub-pixel SP1 described above.

The lower metal layer BML may be the first conductive layer positioned between the substrate SUB and the buffer layer BFL. In one or more embodiments, the lower metal layer BML may be electrically connected to the transistor T_SP1 of the first sub-pixel SP1 to increase the driving range of a certain voltage supplied to the gate electrode GE.

As the gate electrode GE, first terminal EL1, and second terminal EL2 are electrically connected to other circuit elements and/or wiring, the transistor T_SP1 of the first sub-pixel SP1 may be provided as one of the transistors that make up the pixel circuit PXC of the first sub-pixel SP1.

Each of the transistors T_SP2 and T_SP3 of the second sub-pixel SP2 and the third sub-pixel SP3, respectively, may be configured to be substantially identical to the transistor T_SP1 of the first sub-pixels SP1.

As described above, the pixel circuit layer PCL may include circuit elements for each of the first to third sub-pixels SP1 to SP3.

On top of the pixel circuit layer PCL, a display element layer DPL may be arranged. The display element layer DPL may include first, second, and third anode electrodes AE1, AE2, and AE3, a pixel defining layer PDL, the emission structure EMS, and an upper electrode CE.

On the pixel circuit layer PCL (or the via layer VIA), the first to third anode electrodes AE1 to AE3 may each be arranged at (on) the first to third sub-pixels SP1 to SP3. For example, the first anode electrode AE1 may be arranged on the via layer VIA of the first sub-pixel SP1, the second anode electrode AE2 may be arranged on the via layer VIA of the second sub-pixel SP2, and the third anode electrode AE3 may be arranged on the via layer VIA of the third sub-pixel SP3.

Each of the first to third anode electrodes AE1 to AE3 may be electrically connected to the circuit element arranged in the pixel circuit layer PCL through the via hole that penetrates the via layer VIA. For example, the first anode electrode AE1 may be electrically connected to the transistor T_SP1 of the first sub-pixel SP1 through a first via hole VIH1 penetrating the via layer VIA, and the second anode electrode AE2 may be electrically connected to the transistor T_SP2 of the second sub-pixel SP2 through a second via hole VIH2 penetrating the via layer VIA, and the third anode electrode AE3 may be electrically connected to the transistor T_SP3 of the third sub-pixel SP3 through a third via hole VIH3 penetrating the via layer VIA.

In one or more embodiments, each of the first to third anode electrodes AE1 to AE3 may have a shape similar to the first to third emission areas EMA1 to EMA3 of FIG. 4A when viewed in the third direction DR3. For example, the first anode electrode AE1 may have a shape similar to the first emission area EMA1 when viewed in the third direction DR3, the second anode electrode AE2 may have a shape similar to the second emission area EMA2 when viewed in the third direction DR3, and the third anode electrode AE3 may have a shape similar to the third emission area EMA3 when viewed in the third direction DR3, but the present disclosure is not limited thereto.

Each of the first to third anode electrodes AE1 to AE3 may be electrically connected to the corresponding pixel circuit PXC to receive a drive current. The first to third anode electrodes AE1 to AE3 may include, but are not limited to, an opaque conductive material capable of reflecting light. According to one or more embodiments, the first to third anode electrodes AE1 to AE3 may include a transparent conductive material.

The pixel defining layer PDL may be positioned on the first to third anode electrodes AE1 to AE3. The pixel defining layer PDL may include openings OP exposing a portion of the first anode electrode AE1, a portion of the second anode electrode AE2, and a portion of the third anode electrode AE3, respectively. The pixel defining layer PDL may be a structure that defines (or compartmentalizes) the emission area of each of the first to third sub-pixels SP1 to SP3. For example, the pixel defining layer PDL may define the first emission area EMA1 of the first sub-pixel SP1, the second emission area EMA2 of the second sub-pixel SP2, and the third emission area EMA3 of the third sub-pixel SP3.

The pixel defining layer PDL may be formed of an organic insulation film including an organic material. The organic material may include acrylic resins, epoxy resins, phenolic resins, polyamide resins, and/or polyimide resins. According to one or more embodiments, the pixel defining layer PDL may include a light-absorbing material or be applied with a light absorbent to absorb light from the outside. For example, the pixel defining layer PDL may include carbon-based black pigments. However, the present disclosure is not limited thereto.

The pixel defining layer PDL may protrude from the via layer VIA in the third direction DR3.

The emission structure EMS may be arranged on the first to third anode electrodes AE1 to AE3 that are exposed by the openings OP of the pixel defining layer PDL. The emission structure EMS may include, but the present disclosure is not limited to, a light-emitting layer configured to generate light, an electron transport unit configured to transport electrons, and a hole transport unit configured to transport holes.

The emission structure EMS fills the openings OP of the pixel defining layer PDL, and may also be arranged on top of the pixel defining layer PDL, but the present disclosure is not limited thereto. The emission structure EMS may be formed through processes such as vacuum deposition and inkjet printing.

A cathode electrode CE may be arranged on the emission structure EMS. The cathode electrode CE may be a common layer that is commonly provided in the first to third sub-pixels SP1 to SP3. The cathode electrode CE may be provided in the form of plates over the entire area of the display area DA. The cathode electrode CE may function as a half mirror that partially transmits and partially reflects light emitted from the emission structure EMS.

The cathode electrode CE may be a thin metal layer with a thickness to allow light emitted from the emission structure EMS to penetrate it. The cathode electrode CE may be formed of a metallic material or a transparent conductive material to have a relatively decreased thickness. In one or more embodiments, the cathode electrode CE may include at least one of a variety of transparent conductive materials, including indium tin oxide, indium zinc oxide, indium tin zinc oxide, aluminum zinc oxide, gallium zinc oxide, zinc tin oxide, and/or gallium tin oxide. In one or more embodiments, the cathode electrode CE may include at least one of magnesium, silver, and/or a (e.g., any suitable) mixture thereof. However, the material of the cathode electrode CE is not limited to the embodiments described above.

The first anode electrode AE1, a portion of the emission structure EMS overlapping with the first anode electrode AE1, and a portion of the cathode electrode CE overlapping with the first anode electrode AE1 may constitute a first light-emitting element LD1. The second anode electrode AE2, a portion of the emission structure EMS overlapping with the second anode electrode AE2, and a portion of the cathode electrode CE overlapping with the second anode electrode AE2 may constitute a second light-emitting element LD2. The third anode electrode AE3, a portion of the emission structure EMS overlapping with the third anode electrode AE3, and a portion of the cathode electrode CE overlapping with the third anode electrode AE3 may constitute a third light-emitting element LD3.

The display element layer DPL may further include a capping layer CPL arranged on the cathode electrode CE. The capping layer CPL may improve the external light-emitting efficiency through constructive interference. The capping layer CPL may include organic materials, inorganic materials, or composite materials, including organic and inorganic materials. In one or more embodiments, the capping layer CPL may not be provided.

A thin film encapsulation layer TFE may be arranged on the display element layer DPL. The thin film encapsulation layer TFE may cover the display element layer DPL. The thin film encapsulation layer TFE may be configured to prevent or reduce the likelihood of (e.g., protect from) oxygen and/or moisture penetrating into the display element layer DPL. In one or more embodiments, the thin film encapsulation layer TFE may include a structure in which one or more inorganic films and one or more organic films are stacked alternately. For example, the inorganic film may include silicon nitride, silicon oxide, and/or silicon oxynitride. For example, the organic film may include one or more organic insulating materials such as acrylic resins, epoxy resins, phenolic resins, polyamide-based resins, polyimide-based resins, unsaturated polyester-based resins, polyphenylene-based resins, polyphenylene sulfide-based resins, and/or benzocyclobutene. However, the materials in the organic and inorganic films of the thin film encapsulation layer TFE are not limited thereto.

The pixel PXL according to one or more embodiments may further include an upper substrate arranged on the thin film encapsulation layer TFE with an intermediate layer CTL interposed therebetween. The upper substrate may be positioned on the thin film encapsulation layer TFE (or combined with the thin film encapsulation layer TFE) through an adhesive process.

The intermediate layer CTL may be provided and/or formed on the thin film encapsulation layer TFE. The intermediate layer CTL may include an adhesive material to enhance the adhesion between the thin film encapsulation layer TFE and the upper substrate. The intermediate layer CTL may also include a filler including an insulating material that has insulating and adhesive properties. According to one or more embodiments, the intermediate layer CTL may be utilized as a flattening layer (a planarization layer) to mitigate steps due to the configurations of the structures positioned therebelow.

The upper substrate may be positioned on the intermediate layer CTL. The upper substrate may include a color filter layer CFL and a color conversion layer CCL formed by a substantially continuous process on one side of a base layer BSL (e.g., formed by a substantially continuous process on a side facing the thin film encapsulation layer TFE). The upper substrate may be bonded to the thin film encapsulation layer TFE through the intermediate layer CTL. The upper substrate may include the base layer BSL, the color filter layer CFL, a first insulation layer INS1, the color conversion layer CCL, and a second insulation layer INS2 that are sequentially stacked in a direction opposite to the third direction DR3.

The base layer BSL may be a rigid or flexible substrate, and materials or properties thereof are not particularly limited. The base layer BSL may be formed of the same material as the substrate SUB, or it may be formed of a different material from the substrate SUB.

The color filter layer CFL may be provided and/or formed on one side of the base layer BSL.

The color filter layer CFL may be configured to filter light emitted from the emission structure EMS and selectively output light in the wavelength range or color corresponding to each sub-pixel. The color filter layer CFL may include color filters CF each corresponding to the first to third sub-pixels SP1 to SP3. For example, the color filter layer CFL may include a first color filter CF1 corresponding to the first sub-pixel SP1, a second color filter CF2 corresponding to the second sub-pixel SP2, and a third color filter CF3 corresponding to the third sub-pixel SP3. Each of the first and third color filters CF1 to CF3 is capable of allowing light in the wavelength range corresponding to the corresponding sub-pixels to pass through. For example, the first color filter CF1 may allow red light to pass through, the second color filter CF2 may allow green light to pass through, and the third color filter CF3 may allow blue light to pass through.

A first light blocking pattern LBP1 may be positioned between the adjacent color filters CF.

The first light blocking pattern LBP1 may be positioned on one side of the base layer BSL to correspond to the pixel defining layer PDL. The first light blocking pattern LBP1 may include a light blocking material that prevents light leakage between each of the first to third emission areas EMA1 to EMA3 and adjacent emission areas. In one or more embodiments, the first light blocking pattern LBP1 may prevent or reduce the mixing of light emitted from each of the first to third sub-pixels SP1 to SP3 that are positioned adjacent to each other. According to one or more embodiments, the first light blocking pattern LBP1 may not be provided.

On the color filter layer CFL in the opposite direction of (e.g., in the direction opposite to) the third direction DR3, the first insulation layer INS1 may be provided and/or formed. The first insulation layer INS1 may be utilized as a protective layer that covers the color filter layer CFL to protect the color filter layer CFL, but the present disclosure is not limited thereto. The first insulation layer INS1 may be an inorganic insulation film including inorganic materials or an organic insulation film including organic materials. According to one or more embodiments, the first insulation layer INS1 may not be provided.

On one side of the first insulation layer INS1 (e.g., a side facing the thin film encapsulation layer TFE), the color conversion layer CCL may be provided and/or formed.

The color conversion layer CCL may include a first color conversion pattern CCP1, a second color conversion pattern CCP2, a light scattering pattern LSP, and a second light blocking pattern LBP2.

The first color conversion pattern CCP1 may be positioned on one side of the first insulation layer INS1 to correspond to the emission structure EMS of the first sub-pixel SP1 and may include first color conversion particles QD1 that convert the light emitted from the emission structure EMS into red light. In one or more embodiments, the first color conversion layer CCP1 may include a plurality of first color conversion particles QD1 dispersed within a set or predetermined matrix material, such as a base resin. The content (e.g., amount) of the first color conversion particles QD1 in the first color conversion layer CCP1 may be approximately 10% to 60%, but the present disclosure is not limited thereto.

The second color conversion pattern CCP2 may be positioned on one side of the first insulation layer INS1 to correspond to the emission structure EMS of the second sub-pixel SP2 and may include second color conversion particles QD2 that convert light emitted from the emission structure EMS into green light with excellent or suitable color reproducibility. In one or more embodiments, the second color conversion pattern CCP2 may include a plurality of second color conversion particles QD2 dispersed within a set or predetermined matrix material, such as a base resin. The content (e.g., amount) of the second color conversion particles QD2 in the second color conversion pattern CCP2 may be approximately 10% to 60%, but the present disclosure is not limited thereto.

The light scattering pattern LSP may be positioned on one side of the first insulation layer INS1 to correspond to the emission structure EMS of the third sub-pixel SP3 and may be a transparent layer (or a transparent window) that transmits the light emitted from the emission structure EMS as it is. The light scattering pattern LSP may include scattering particles SCT to scatter the light emitted from the emission structure EMS in various directions.

The second light blocking pattern LBP2 (or a bank) may be arranged on one side of the first insulation layer INS1 to correspond to the pixel defining layer PDL (or the first light blocking pattern LBP1). The second light blocking pattern LBP2 may be a structure that defines the formation site of the first color conversion pattern CCP1, the formation site of the second color conversion pattern CCP2, and the formation site of the light scattering pattern LSP.

The second light blocking pattern LBP2 may include at least one light blocking material and/or reflective material, or it may include the same material as the first light blocking pattern LBP1.

On one side of the color conversion layer CCL in the opposite direction of the third direction DR3, the second insulation layer INS2 may be provided and/or formed. In one or more embodiments, the second insulation layer INS2 may be utilized as a protective layer to protect the color conversion layer CCL by covering the color conversion layer CCL, but the present disclosure is not limited thereto. The second insulation layer INS2 may be an inorganic insulation film including inorganic materials or an organic insulation film including organic materials.

As described above, as the color conversion layer CCL and the color filter layer CFL are arranged on top of the thin film encapsulation layer TFE, the light emission efficiency of each of the first, second, and third sub-pixels SP1, SP2, SP3 may further be improved by emitting light after converting the light emitted from each of the emission structures EMS of the first, second, and third sub-pixels SP1, SP2, SP3 into light with excellent or suitable color reproducibility.

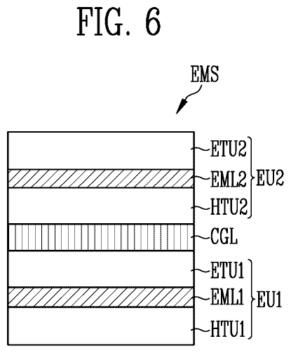

FIG. 6 is a schematic cross-sectional diagram illustrating the emission structure EMS included in one of the first to third light-emitting elements of FIG. 5, according to one or more embodiments of the present disclosure.

Referring to FIG. 5 and FIG. 6, the emission structure EMS may have a tandem structure in which a first emission unit EU1 and a second emission unit EU2 are stacked. The emission structure EMS may be configured to be substantially identical in each of the first to third light-emitting elements LD1 to LD3 of FIG. 5.

Each of the first and second emission units EU1 and EU2 may include at least one light-emitting layer that generates light according to the applied current. The first emission unit EU1 may include a first light-emitting layer EML1, a first electron transport unit ETU1, and a first hole transport unit HTU1. The first light-emitting layer EML1 may be arranged between the first electron transport unit ETU1 and the first hole transport unit HTU1. The second emission unit EU2 may include a second light-emitting layer EML2, a second electron transport unit ETU2, and a second hole transport unit HTU2. The second light-emitting layer EML2 may be arranged between the second electron transport unit ETU2 and the second hole transport unit HTU2.

Each of the first and second hole transport units HTU1 and HTU2 may include at least one of a hole injection layer and a hole transport layer and may further include a hole buffer layer and/or an electron retarding layer, as desired and/or needed. The first and second hole transport units HTU1 and HTU2 may have the same configuration or different configurations from each other.

Each of the first and second electron transport units ETU1 and ETU2 may include at least one of an electron injection layer and/or an electron transport layer and may further include an electron buffer layer and/or a hole retarding layer, as desired and/or needed. The first and second electronic transport units ETU1 and ETU2 may have the same configuration or different configurations from each other.

An intermediate layer (or a connection layer), which may be provided in the form of a charge generating layer CGL, may be arranged between the first emission unit EU1 and the second emission unit EU2 to connect the first emission unit EU1 and the second emission units EU2 to each other. Hereinafter, the charge generating layer CGL is referred to as the intermediate layer. In one or more embodiments, the intermediate layer CGL may have a stacked structure of p dopant layers and n dopant layers. For example, the p dopant layer may include p-type (kind) dopants such as hexaazatriphenylenehexacarbonitrile (HAT-CN), tetracyanoquinodimethane (TCNQ), and/or 2-(7-dicyanomethylene-1,3,4,5,6,8,9,10-octafluoro-7H-pyrene-2-ylidene)-malononitrile (NDP-9), and the n dopant layer may include alkali metals, alkali earth metals, lanthanide-based metals, and/or a (e.g., any suitable) combination thereof. However, the structure (or material) of the intermediate layer CGL is not limited to the embodiments described above. In one or more embodiments, compared to the first and second emission units EU1, EU2 of the intermediate layer CGL, it is possible to have conductivity by including a material with relatively high charge conductivity (or charge mobility).

In one or more embodiments, the first light-emitting layer EML1 and the second light-emitting layer EML2 may generate light of different colors, but are not limited thereto. According to one or more embodiments, the first light-emitting layer EML1 and the second light-emitting layer EML2 may generate light of the same color.

In one or more embodiments described above, the emission structure EMS is described as a tandem structure in which the first emission unit EU1 and the second emission unit EU2 are stacked, but the present disclosure is not limited thereto. According to one or more embodiments, the emission structure EMS may be configured as a tandem structure in which three emission units are stacked.

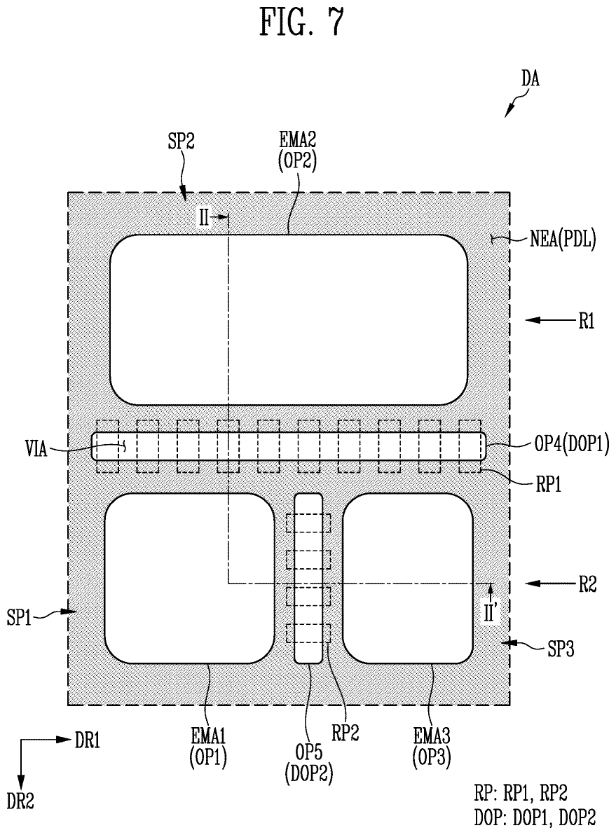

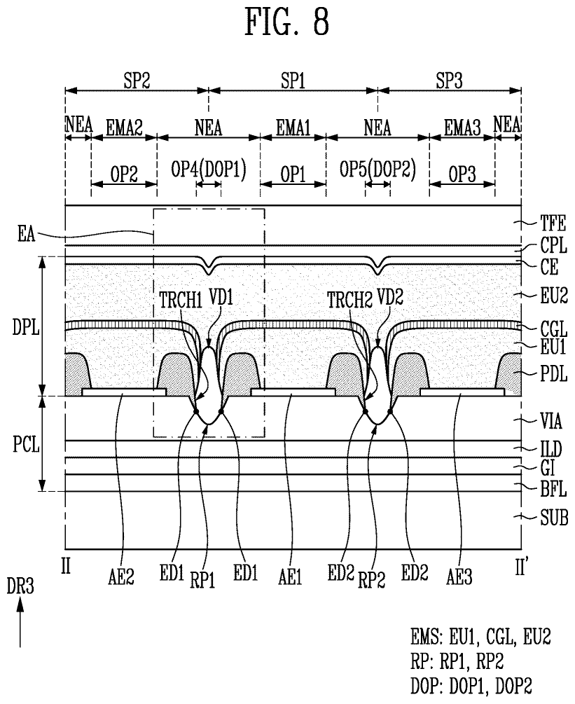

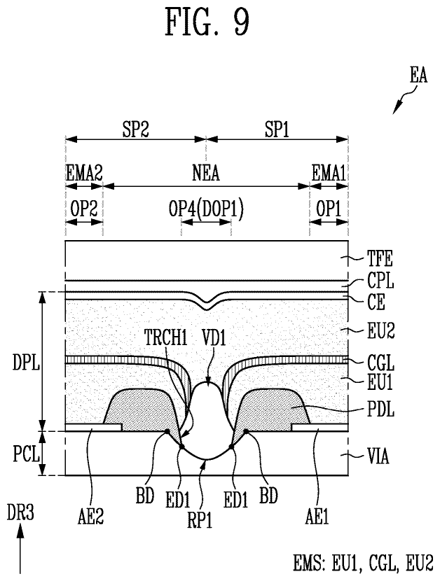

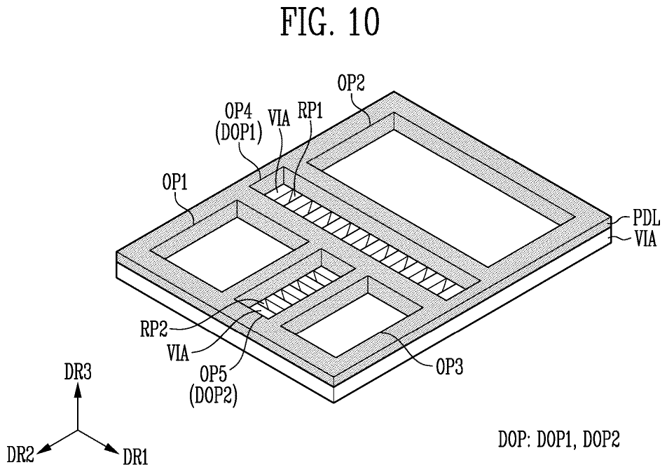

FIG. 7 is a schematic plan view illustrating an area of the display area DA of FIG. 1, according to one or more embodiments of the present disclosure, FIG. 8 is a schematic cross-sectional diagram taken along the line II-II′ of FIG. 7, according to one or more embodiments of the present disclosure, FIG. 9 is an enlarged schematic cross-sectional diagram of an area EA of FIG. 8, according to one or more embodiments of the present disclosure, and FIG. 10 is a schematic perspective view illustrating a via layer VIA and a pixel defining layer PDL of FIG. 7, according to one or more embodiments of the present disclosure. In FIG. 8, for clarity and conciseness in explanation, the representation of the upper substrate described in reference to FIG. 5 is not provided.

In FIG. 7 to FIG. 10, in order to avoid duplicated explanations, the description will be set forth based on the differences from the one or more embodiments described above.

Referring to FIG. 1 and FIG. 7 to FIG. 10, the display area DA may be divided into pixel rows R1 and R2. The pixel rows R1 and R2 may be arranged in the second direction DR2 by extending in the first direction DR1.

The first sub-pixel SP1, the second sub-pixel SP2, and the third sub-pixel SP3 may be arranged in the display area DA. The second sub-pixel SP2 may be positioned in (over) the first and second columns in the first pixel row R1, the first sub-pixel SP1 may be positioned in the first column in the second pixel row R2, and the third sub-pixel SP3 may be positioned in the second column in the second pixel row R2.

The first sub-pixel SP1 may include the first emission area EMA1, the second sub-pixel SP2 may include the second emission area EMA2, and the third sub-pixel SP3 may include the third emission area EMA3. The non-emission area NEA may be arranged around the first emission area EMA1, the second emission area EMA2, and the third emission area EMA3. The pixel defining layer PDL may be arranged on the non-emission area NEA. The first sub-pixel SP1 may be to emit light of a first color, the second sub-pixel SP2 may be to emit light of a second color, and the third sub-pixel SP3 may be to emit light of a third color. The light of the first color may be red, the light of the second color may be green, and the light of the third color may be blue light, but the present disclosure is not limited thereto.

The first sub-pixel SP1 and the third sub-pixel SP3 may be arranged in the first direction DR1. The second sub-pixel SP2 may be arranged in the direction opposite to (e.g., opposite direction of) the second direction DR2 for each of the first and third sub-pixels SP1 and SP3. The first sub-pixel SP1 may have an area greater than the third sub-pixel SP3, and the second sub-pixel SP2 may have an area greater than the first sub-pixel SP1. Accordingly, the first emission area EMA1 may have an area greater than the third emission area EMA3, and the second emission area EMA2 may have an area greater than the first emission area EMA1.

In one or more embodiments, each of the first to third sub-pixels SP1 to SP3 may include the substrate SUB, the pixel circuit layer PCL, the display element layer DPL, and the thin film encapsulation layer TFE.

In one or more embodiments, the via layer VIA included in the pixel circuit layer PCL may include a recessed pattern RP in an area of the non-emission area NEA. The recessed pattern RP may be formed by the via layer VIA being recessed in the direction facing (e.g., towards) the substrate SUB in the third direction DR3. For example, the recessed pattern RP may be an area that is stepped from one side of the via layer VIA (e.g., the upper surface of the via layer VIA) toward the substrate SUB. The via layer VIA including the recessed pattern RP may have a less thickness than the via layer VIA that does not include the recessed pattern RP. In one or more embodiments, the via layer VIA may be an organic film including an organic material.

The recessed pattern RP of the via layer VIA may be positioned in an area of the non-emission area NEA, e.g., in the non-emission area NEA between adjacent sub-pixels. The recessed pattern RP may include a first recessed pattern RP1 and a second recessed pattern RP2. The first recessed pattern RP1 and the second recessed pattern RP2 may extend in a direction that is different from each other in a plan view. For example, the first recessed pattern RP1 may extend in the second direction DR2, and the second recessed pattern RP2 may extend in the first direction DR1.

A plurality of first recessed patterns RP1 may be provided. For example, the first recessed pattern RP1 may extend in the second direction DR2 in a plan view and include the plurality of first recessed patterns RP1 that are arranged along the first direction DR1 intersecting
the second direction DR2. A plurality of second recessed patterns RP2 may be provided. For example, the second recessed pattern RP2 may extent in the first direction DR1 in a plan view and include the plurality of second recessed patterns RP2 that are arranged along the second direction DR2 intersecting the first direction DR1.

On the via layer VIA including the recessed pattern RP, the first anode electrode AE1, the second anode electrode AE2, and the third anode electrode AE3 may be arranged. The first to third anode electrodes AE1 to AE3 may be arranged to be spaced and/or apart (e.g., spaced apart or separated) from each other. The first to third anode electrodes AE1 to AE3 may be arranged on the top surface of the via layer VIA so as not to overlap with the recessed pattern RP of the via layer VIA.

The via layer VIA may be arranged in the non-emission area NEA, and the pixel defining layer PDL may be arranged on the first to third anode electrodes AE1 to AE3. The pixel defining layer PDL may include a plurality of openings (including openings OP as described, e.g., with respect to FIG. 5). For example, the pixel defining layer PDL may include a first opening OP1, a second opening OP2, a third opening OP3, a fourth opening OP4, and a fifth opening OP5. In one or more embodiments, the pixel defining layer PDL may be an organic film including an organic material.

The first opening OP1 may be a light-emitting opening that defines the first emission area EMA1, the second opening OP2 may be a light-emitting opening that defines the second emission area EMA2, and the third opening OP3 may be a light-emitting opening that defines the third emission area EMA3. The first opening OP1 of the pixel defining layer PDL may expose a portion of the first anode electrode AE1, the second opening OP2 of the pixel defining layer PDL may expose a portion of the second anode electrode AE2, and the third opening OP3 of the pixel defining layer PDL may expose a portion of the third anode electrode AE3.

The fourth opening OP4 and fifth opening OP5 may be dummy openings DOP positioned in the non-emission area NEA. The fourth opening OP4 and the fifth opening OP5 may overlap with the recessed patterns RP1 and RP2 of the via layer VIA, respectively. The fourth opening OP4 and the fifth opening OP5 may be arranged to be spaced and/or apart (e.g., spaced apart or separated).

The fourth opening OP4 (or a first dummy opening DOP1) may be positioned in the non-emission area NEA between the second sub-pixel SP2 and the first sub-pixel SP1 and in the non-emission area NEA between the second sub-pixel SP2 and the third sub-pixel SP3. The fourth opening OP4 may extend in the first direction DR1 in the non-emission area NEA between the second sub-pixel SP2 and the first sub-pixel SP1 and in the non-emission area NEA between the second sub-pixel SP2 and the third sub-pixel SP3.

The fifth opening OP5 (or a second dummy opening DOP2) may be positioned in the non-emission area NEA between the first sub-pixel SP1 and the third sub-pixel SP3. The fifth opening OP5 may extend in the second direction DR2 intersecting the first direction DR1 in the non-emission area NEA between the first sub-pixel SP1 and the third sub-pixel SP3. The fourth opening OP4 and the fifth opening OP5 may each extend in a different direction.

In a plan view, the recessed pattern RP of the via layer VIA and the dummy opening DOP of the pixel defining layer PDL may intersect (overlap). For example, the first recessed pattern RP1 of the via layer VIA and the fourth opening OP4 (or the first dummy opening DOP1) of the pixel defining layer PDL may intersect (overlap) each other, and the second recessed pattern RP2 of the via layer VIA and the fifth opening OP5 (or the second dummy opening DOP2) of the pixel defining layer PDL may intersect (overlap) each other. The fourth opening OP4 may intersect (overlap) the plurality of first recessed patterns RP1, and the fifth opening OP5 may intersect (overlap) the plurality of second recessed patterns RP2.

The ends ED1 of both sides (e.g., first ends ED1 of the pixel defining layer that are at opposing sides) of the pixel defining layer PDL with the fourth opening OP4 of the pixel defining layer PDL (or the first dummy opening DOP1) interposed therebetween may be arranged on (in) the first recessed pattern RP1 of the via layer VIA (e.g., first ends ED1 of the pixel defining layer PDL that are at opposing sides of the pixel defining layer PDL may define the fourth opening OP4 of the pixel defining layer PDL (or the first dummy opening DOP1)). For example, the ends ED1 of both sides (e.g., the first ends ED1 at opposing sides) of the pixel defining layer PDL with the fourth opening OP4 of the pixel defining layer PDL interposed therebetween (e.g., defining the fourth opening OP4) may be arranged on (in) the plurality of first recessed patterns RP1, respectively. The ends ED1 of both sides (e.g., the first ends ED1 at opposing sides) of the pixel defining layer PDL may contact a portion of the first recessed pattern RP1 of the via layer VIA. The ends ED1 of both sides (e.g., the first ends ED1 at opposing sides) of the pixel defining layer PDL with the fourth opening OP4 interposed therebetween (e.g., defining the fourth opening OP4) may contact the first recessed pattern RP1 of the via layer VIA to configure a first trench TRCH1 in the non-emission area NEA. At this time, the upper surface of the via layer VIA and a boundary point BD (see, e.g., FIG. 9) of the first recessed pattern RP1 may be covered by the pixel defining layer PDL. For example, the ends ED1 of both sides (e.g., the first ends ED1 at opposing sides) of the pixel defining layer PDL, with the fourth opening OP4 interposed between them, may be arranged in the first recessed pattern RP1 of the via layer VIA. This configuration may define a first trench TRCH1 in the non-emission area NEA, with the upper surface of the via layer VIA and a boundary point BD covered by the pixel defining layer PDL.

The ends ED2 of both sides (e.g., second ends ED2 of the pixel defining layer at opposing sides) of the pixel defining layer PDL with the fifth opening OP5 of the pixel defining layer PDL (or the second dummy opening DOP2) interposed therebetween may be arranged on (in) the second recessed pattern RP2 of the via layer VIA (e.g., second ends ED2 of the pixel defining layer PDL that are at opposing sides of the pixel defining layer PDL may define the fifth opening OP5 of the pixel defining layer PDL (or the second dummy opening DOP2)). For example, the ends ED2 of both sides (e.g., the second ends ED2 at opposing sides) of the pixel defining layer PDL with the fifth opening OP5 of the pixel defining layer PDL interposed therebetween (e.g., defining the fifth opening OP5) may be arranged on (in) the plurality of second recessed patterns RP2, respectively. The ends ED2 of both sides (e.g., the second ends ED2 at opposing sides) of the pixel defining layer PDL may contact a portion of the second recessed pattern RP2 of the via layer VIA. The ends ED2 of both sides (e.g., the second ends ED2 at opposing sides) of the pixel defining layer PDL with the fifth opening OP5 interposed therebetween (e.g., defining the fifth opening OP5) may contact the second recessed pattern RP2 of the via layer VIA to configure a second trench TRCH2 in the non-emission area NEA. At this time, the boundary point between the upper surface of the via layer VIA and the second recessed pattern RP2 may be covered by the pixel defining layer PDL. For example, the ends ED2 of both sides (e.g., the second ends ED2 at opposing sides) of the pixel defining layer PDL, with the fifth opening OP5 interposed between them, may be arranged in the second recessed pattern RP2 of the via layer VIA. This configuration may define a second trench TRCH2 in the non-emission area NEA, with the boundary point between the upper surface of the via layer VIA and the second recessed pattern RP2 covered by the pixel defining layer PDL.

The first trench TRCH1 may be formed in an area of the non-emission area NEA where the fourth opening OP4 of the pixel defining layer PDL and the first recessed pattern RP1 of the via layer VIA intersect (overlap). The second trench TRCH2 may be formed in an area of the non-emission area NEA where the fifth opening OP5 of the pixel defining layer PDL and the second recessed pattern RP2 of the via layer VIA intersect (overlap).

The emission structure EMS may be arranged on the first to third anode electrodes AE1 to AE3 and the pixel defining layer PDL. The emission structure EMS may include the first emission unit EU1 and the second emission unit EU2. The emission structure EMS may further include the intermediate layer CGL arranged between the first emission unit EU1 and the second emission unit EU2. In one or more embodiments, each of the first emission unit EU1 and the second emission unit EU2 may include the light-emitting layer that generates light according to the applied current. The first emission unit EU1 may be the same as the first emission unit EU1 described in reference to FIG. 6, and the second emission unit EU2 may be the same as the second emission unit EU2 described in reference to FIG. 6.

The first emission unit EU1 and the second emission unit EU2 may each include a charge transport unit, the light-emitting layer, the electron transport unit, and the buffer layer, including a material with a relatively lower charge conductivity (or charge mobility) than the intermediate layer CGL. In one or more embodiments, the first emission unit EU1 and the second emission unit EU2 may include a material with relatively greater insulating properties than the intermediate layer CGL. In such embodiments, even though the first emission unit EU1 and the second emission unit EU2 are connected to each other at (on) the first and second trenches TRCH1 and TRCH2, no current may be transmitted to adjacent sub-pixels.

The first emission unit EU1 may be arranged on the pixel defining layer PDL and anode electrodes in an area of the non-emission area NEA of adjacent sub-pixels. In the non-emission area NEA, the first emission unit EU1 may include disconnected parts (or open parts) that are separated from each other at (in) the first and second trenches TRCH1 and TRCH2 positioned in the boundary area between adjacent sub-pixels. The disconnected parts may be defined by portions at which the first emission unit EU1 is disconnected, and/or not formed continuously, in the first and second trenches TRCH1 and TRCH2. In such embodiments, the first emission unit EU1 of the adjacent sub-pixels may be separated from each other. For example, as shown in FIG. 8, the first emission unit EU1 at the second sub-pixel SP2 may be separated from the first emission unit EU1 at the first sub-pixel SP1, and the first emission unit EU1 at the first sub-pixel SP1 may be separated from the first emission unit EU1 at the third sub-pixel SP3. The intermediate layer CGL may be arranged on the first emission unit EU1.

The intermediate layer CGL may include disconnected parts that are respectively separated at (in) the first and second trenches TRCH1 and TRCH2. For example, as shown in FIG. 8, the intermediate layer CGL at the second sub-pixel SP2 may be separated from the intermediate layer CGL at the first sub-pixel SP1, and the intermediate layer CGL at the first sub-pixel SP1 may be separated from the intermediate layer CGL at the third sub-pixel SP3.

The second emission unit EU2 may be arranged on the intermediate layer CGL. The second emission unit EU2 may be formed on the intermediate layer CGL to have a relatively high thickness. Accordingly, the second emission unit EU2 may not be disconnected in the non-emission area NEA, i.e., the boundary area between adjacent sub-pixels. For example, as shown in FIG. 8, the second emission unit EU2 at the second sub-pixel SP2, the second emission unit EU2 at the first sub-pixel SP1, and the second emission unit EU2 at the third sub-pixel SP3 may be connected to each other. According to one or more embodiments, at least a portion of the second emission unit EU2 at one of two adjacent sub-pixels and at least a portion of the second emission unit EU2 at the other adjacent sub-pixel may be disconnected in the first and/or second trenches TRCH1 and TRCH2. For example, the lower surface (e.g., one side in contact with the intermediate layer CGL) of the second emission unit EU2 at adjacent sub-pixels may be disconnected in the first and second trenches TRCH1 and TRCH2, respectively, and the upper surface (e.g., one side in contact with the cathode electrode CE) facing (e.g., opposite to) the lower surface in the third direction DR3 may be connected to each other. Accordingly, the second emission unit EU2 may not be disconnected in the first and second trenches TRCH1 and TRCH2.

The cathode electrode CE may be arranged on the second emission unit EU2. The cathode electrode CE may be formed of a metal including a conductive material. The second emission unit EU2 arranged at the bottom of the cathode electrode CE may be formed to have a relatively greater thickness than the first emission unit EU1. The thickness of the second emission unit EU2 may be a gap between the intermediate layer CGL and the cathode electrode CE. For example, the thickness of the second emission unit EU2, which corresponds to a gap between the intermediate layer CGL and the cathode electrode CE, may be greater than that of the first emission unit EU1. This is to prevent or reduce defects caused by short circuits with the conductive intermediate layer as the cathode electrode CE includes a material with high charge conductivity (or charge mobility), while preventing or reducing the likelihood of the cathode electrode CE being disconnected due to the step of the components positioned therebelow (e.g., the intermediate layer CGL and the first emission unit EU1). Due to the second emission unit EU2 having a large thickness, the gap between the cathode electrode CE and the intermediate layer CGL may be further secured, thereby preventing or reducing defects in which the cathode electrode CE and the intermediate layer CGL are short-circuited. In one or more embodiments, due to the second emission unit EU2, the step of the components positioned at the bottom is smoothed out, such that the step coverage of the cathode electrode CE arranged on the second emission unit EU is improved, thereby preventing or reducing the likelihood of the cathode electrode CE failing due to being cut out (on e.g., disconnected at) the first and second trenches TRCH1 and TRCH2. For example, the cathode electrode CE may be arranged on the second emission unit EU2, which has a greater thickness than the first emission unit EU1. This thickness, corresponding to the gap between the intermediate layer CGL and the cathode electrode CE, helps prevent defects caused by short circuits with the conductive intermediate layer. The increased thickness of the second emission unit EU2 secures the gap, reducing the likelihood of short circuits and improving the step coverage of the cathode electrode CE, thereby preventing or reducing the likelihood of disconnection at the first and second trenches TRCH1 and TRCH2.

In one or more embodiments, a first void VD1 may be formed in the first trench TRCH1, and a second void VD2 may be formed in the second trench TRCH2. The first void VD1 may be formed by some configurations of the disconnected emission structure EMS in the first trench TRCH1 and the remainder of the connected emission structure EMS. The second void VD2 may be formed by some configurations of the emission structure EMS disconnected in the second trench TRCH2 and the remainder of the connected emission structure EMS. For example, the first void VD1 may be enclosed by the first recessed pattern RP1 of the via layer VIA, ends ED1 of both sides (e.g., the first ends ED1 at opposing sides) of the pixel defining layer PDL with the fourth opening OP4 (or the first dummy opening DOP1) interposed therebetween, the first emission unit EU1, the intermediate layer CGL, and the second emission unit EU2. The second void VD2 may be enclosed by the second recessed pattern RP2 of the via layer VIA, ends ED2 of both sides (e.g., the second ends ED2 at opposing sides) of the pixel defining layer PDL with the fifth opening OP5 (or the second dummy opening DOP2) interposed therebetween, the first emission unit EU1, the intermediate layer CGL, and the second emission unit EU2.

According to one or more embodiments described above, in the non-emission area NEA between the second sub-pixel SP2 and the first sub-pixel SP1 and the non-emission area NEA between the second sub-pixel SP2 and the third sub-pixel SP3, ends ED1 of both sides (e.g., the first ends ED1 at opposing sides) of the pixel defining layer PDL with the fourth opening OP4 interposed therebetween may be positioned on the first recessed patterns RP1 as the first recessed pattern RP1 of the via layer VIA and the fourth opening OP4 (or the first dummy opening DOP1) of the pixel defining layer PDL intersect (overlap). In one or more embodiments, the first recessed pattern RP1 is recessed in a direction from the upper surface of the via layer VIA towards the substrate SUB to have a concave shape, and the ends ED1 of both sides (e.g., the first ends ED1 at opposing sides) of the pixel defining layer PDL may be arranged on the first recessed pattern RP1 to have a convex shape. Accordingly, a step inflection point may occur at a point of contact between the first recessed pattern RP1 and the ends ED1 of both sides (e.g., the first ends ED1 at opposing sides) of the pixel defining layer PDL. Due to the step inflection point, the tilt of both sides (e.g., of the first ends ED1 at opposing sides) of the pixel defining layer PDL with the fourth opening OP4 interposed therebetween may increase. In other words, the first ends ED1 that are at opposing sides of the pixel defining layer PDL and that define the fourth opening OP4 may have an increased angle relative to the substrate SUB. If (e.g., when) the tilt (angle) of both sides (e.g., of the first ends ED1 at opposing sides) of the pixel defining layer PDL with the fourth opening OP4 interposed therebetween increases, some configurations (e.g., layers) of the emission structures EMS arranged on the pixel defining layer PDL, e.g., the electrical connection of the intermediate layer CGL, may easily be broken (e.g., disconnected), so that the intermediate layer CGL may have a high electrical resistant structure between adjacent sub-pixels. Accordingly, upon the operation of the display device (see, e.g., “DD” in FIG. 1), the current outflowing from each of the first to third sub-pixels SP1 to SP3 to the neighboring sub-pixels through the layers included in the emission structure EMS may be reduced. For example, in the non-emission area NEA between the second sub-pixel SP2 and the first sub-pixel SP1, and between the second sub-pixel SP2 and the third sub-pixel SP3, the ends ED1 of both sides (e.g., the first ends ED1 at opposing sides) of the pixel defining layer PDL, with the fourth opening OP4 interposed between them, may be positioned on the first recessed patterns RP1 of the via layer VIA. This arrangement may create a step inflection point, increasing the tilt of the pixel defining layer PDL. Consequently, the electrical connection of the intermediate layer CGL may be easily broken, resulting in a high electrical resistance structure between adjacent sub-pixels and reducing current outflow from each sub-pixel.

In one or more embodiments, according to one or more embodiments described above, as the second recessed pattern RP2 of the via layer VIA and the fifth opening OP5 (or the second dummy opening DOP2) of the pixel defining layer PDL intersect (overlap) in the non-emission area NEA between the first sub-pixel SP1 and the third sub-pixel SP3, ends ED2 of both sides (e.g., the second ends ED2 at opposing sides) of the pixel defining layer PDL with the fifth opening OP5 interposed therebetween may be positioned on the second recessed pattern RP2. In one or more embodiments, the second recessed pattern RP2 is recessed in a direction from the upper surface of the via layer VIA to the substrate SUB to have a concave shape, and the ends ED2 of both sides (e.g., the second ends ED2 at opposing sides) of the pixel defining layer PDL is arranged on the second recessed pattern RP2 to have a convex shape. Accordingly, a step inflection point may occur at a point of contact between the second recessed pattern RP2 and the ends ED2 of both sides (e.g., the second ends ED2 at opposing sides) of the pixel defining layer PDL. Due to the step inflection point, the tilt of both sides (e.g., of the second ends ED2 at opposing sides) of the pixel defining layer PDL with the fifth opening OP5 interposed therebetween may increase. In other words, the second ends ED2 that are at opposing sides of the pixel defining layer PDL and that define the fifth opening OP5 may have an increased angle relative to the substrate SUB. If (e.g., when) the tilt (angle) of both sides (e.g., of the second ends ED2 at opposing sides) of the pixel defining layer PDL with the fifth opening OP5 interposed therebetween increases, some configurations (e.g., layers) of the emission structure EMS arranged on the pixel defining layer PDL, e.g., the electrical connection of the intermediate layer CGL, may easily be cut out (e.g., broken or disconnected) so that the intermediate layer CGL may have a high electrical resistant structure between adjacent sub-pixels. Accordingly, upon the operation of the display device DD, the current outflowing from each of the first to third sub-pixels SP1 to SP3 to the neighboring sub-pixels through the layers included in the emission structure EMS may be reduced. For example, in the non-emission area NEA between the first sub-pixel SP1 and the third sub-pixel SP3, the ends ED2 of both sides (e.g., the second ends ED2 at opposing sides) of the pixel defining layer PDL, with the fifth opening OP5 interposed between them, may be positioned on the second recessed pattern RP2 of the via layer VIA. This arrangement may create a step inflection point, increasing the tilt of the pixel defining layer PDL. Consequently, the electrical connection of the intermediate layer CGL may be easily broken, resulting in a high electrical resistance structure between adjacent sub-pixels and reducing current outflow from each sub-pixel.

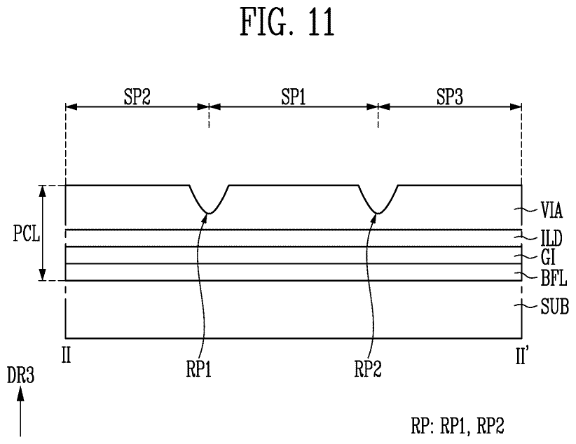

FIG. 11 to FIG. 15 are schematic cross-sectional views corresponding to the line II-II′ of FIG. 7, describing a manufacturing method of a display device according to one or more embodiments of the present disclosure.

In FIG. 7 and FIG. 11 to FIG. 15, for convenience in explanation, descriptions that are redundant of the one or more embodiments above may not be repeated.

Referring to FIG. 7 and FIG. 11, the via layer VIA is formed on the interlayer insulation layer ILD. For example, the via layer VIA is formed on top of the interlayer insulation layer ILD of adjacent sub-pixels.

A photolithography process using a mask is used to form the via layer VIA on the interlayer insulation layer ILD. For example, a base material of the via layer VIA is applied onto the interlayer insulation layer ILD, exposed using a mask, and then developed to form the via layer VIA. In the process of exposure, the amount of light is adjusted to form the first recessed pattern RP1 and the second recessed pattern RP2.

In a plan view, the first recessed pattern RP1 may extend in the second direction DR2, and the second recessed pattern RP2 may extend in the first direction DR1. A plurality of first recessed patterns RP1 and a plurality of second recessed patterns RP2 may be provided.

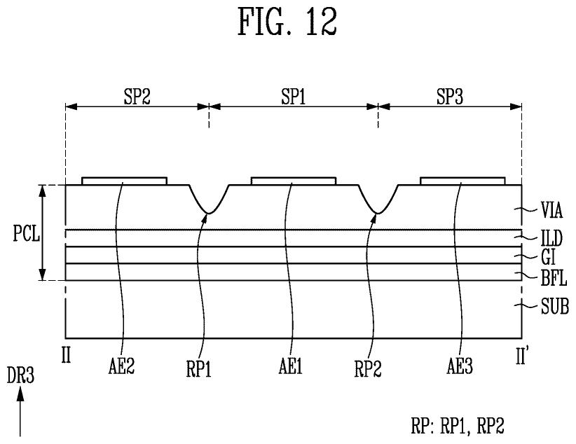

Referring to FIG. 7 and FIG. 12, the first anode electrode AE1, the second anode electrode AE2, and the third anode electrode AE3 are formed on the via layer VIA. The first anode electrode AE1, the second anode electrode AE2, and the third anode electrode AE3 may be arranged to be spaced and/or apart (e.g., spaced apart or separated) from each other on the upper surface of the via layer VIA.

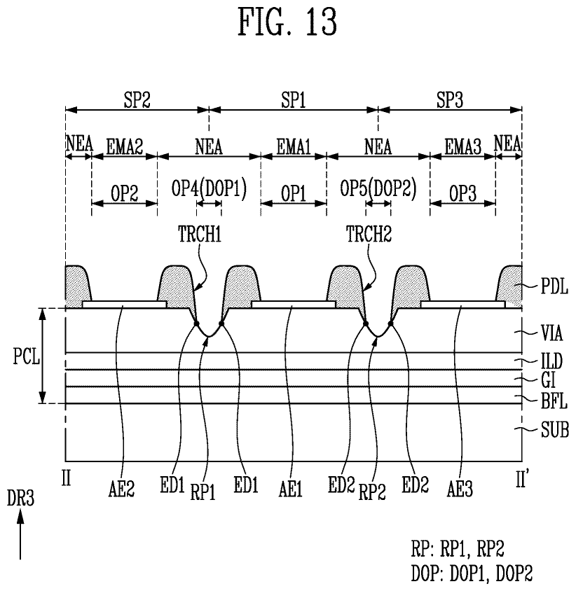

Referring to FIG. 7 and FIG. 13, the pixel defining layer PDL is formed on the first to third anode electrodes AE1 to AE3 and the via layer VIA. For example, the pixel defining layer PDL may be formed over the whole area on the first anode electrode AE1, second anode electrode AE2, third anode electrode AE3, and via layer VIA.

The pixel defining layer PDL may include the light-emitting opening and the dummy opening DOP. For example, the light-emitting opening may include the first opening OP1 forming the first emission area EMA1 of the first sub-pixel SP1, the second opening OP2 forming the second emission area EMA2 of the second sub-pixel SP2, and the third opening OP3 forming the third emission area EMA3 of the third sub-pixel SP3. The dummy opening DOP may include the fourth opening OP4 (or the first dummy opening DOP1) and the fifth opening OP5 (or the second dummy opening DOP2) positioned in areas of the non-emission area NEA around (between) the first to third emission areas EMA1 to EMA3.

The first opening OP1 may expose a portion of the first anode electrode AE1, the second opening OP2 may expose a portion of the second anode electrode AE2, and the third opening OP3 may expose a portion of the third anode electrode AE3. The fourth opening OP4 may overlap with the first recessed patterns RP1 of the via layer VIA, and the fifth opening OP5 may overlap with the second recessed patterns RP2 of the via layer VIA.

In a plan view, the fourth opening OP4 may extend in the first direction DR1 and intersect (overlap) a plurality of first recessed patterns RP1. In an area of the non-emission area NEA between adjacent sub-pixels, the first trench TRCH1 may be formed as the fourth opening OP4 of the pixel defining layer PDL and each of the first recessed patterns RP1 of the via layer VIA may intersect (overlap) the fourth opening OP4 (e.g., the first trench TRCH1).

In a plan view, the fifth opening OP5 may extend in the second direction DR2 and intersect (overlap) a plurality of second recessed patterns RP2. In an area of the non-emission area NEA between adjacent sub-pixels, the second trench TRCH2 may be formed as the fifth opening OP5 of the pixel defining layer PDL and each of the second recessed patterns RP2 of the via layer VIA may intersect (overlap) the fifth opening OP5 (e.g., the second trench TRCH2).

The ends ED1 of both sides (e.g., the first ends ED1 at opposing sides) of the pixel defining layer PDL with the fourth opening OP4 interposed therebetween may contact the first recessed pattern RP1. The ends ED2 of both sides (e.g., the second ends ED2 at opposing sides) of the pixel defining layer PDL with the fifth opening OP5 interposed therebetween may contact the second recessed pattern RP2. A step inflection point may occur at a point of contact between each of the first recessed patterns RP1 and the ends ED1 of both sides (e.g., the second ends ED2 at opposing sides) of the pixel defining layer PDL. A step inflection point may occur at a point of contact between each of the second recessed patterns RP2 and the ends ED2 of both sides (e.g., the second ends ED2 at opposing sides) of the pixel defining layer PDL. Due to the step inflection points, the tilt (angle) of both sides (e.g., the first and second ends ED1 and ED2) of the pixel defining layer PDL with the fourth and fifth openings OP4 and OP5 interposed therebetween, respectively, may increase.

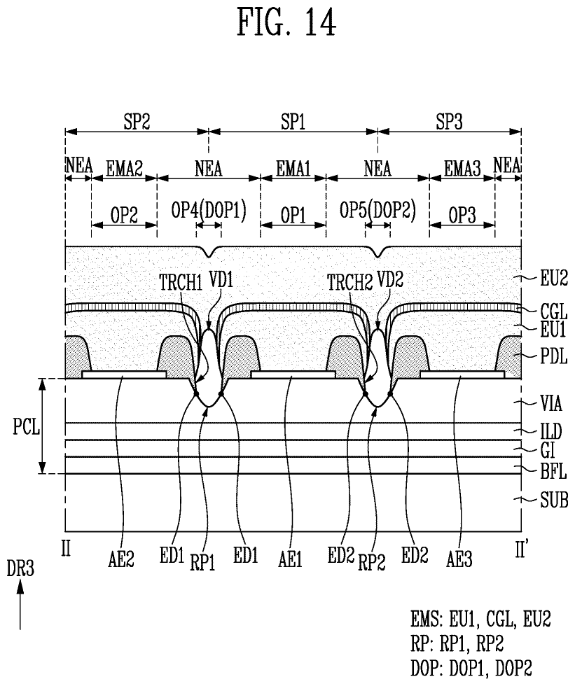

Referring to FIG. 7 and FIG. 14, the emission structure EMS is formed on the pixel defining layer PDL. For example, the emission structure EMS may include the first emission unit EU1, the intermediate layer CGL, and the second emission unit EU2 that are sequentially stacked in a third direction DR3. Each of the first emission unit EU1 and the intermediate layer CGL may have a disconnected part in the first and second trenches TRCH1 and TRCH2. The second emission unit EU2 may not be disconnected in the first and second trenches TRCH1 and TRCH2.

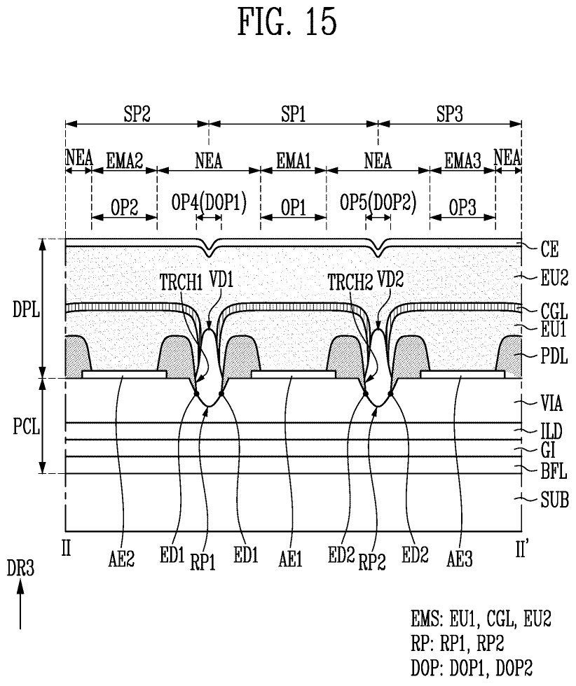

Referring to FIG. 7 and FIG. 15, the cathode electrode CE is formed on the emission structure EMS. For example, the cathode electrode CE may be a common layer that is commonly provided to adjacent sub-pixels, e.g., first to third sub-pixels SP1 to SP3.

Subsequently, the remaining configurations shown in FIG. 8, e.g., the capping layer CPL and the thin film encapsulation layer TFE may be formed sequentially.

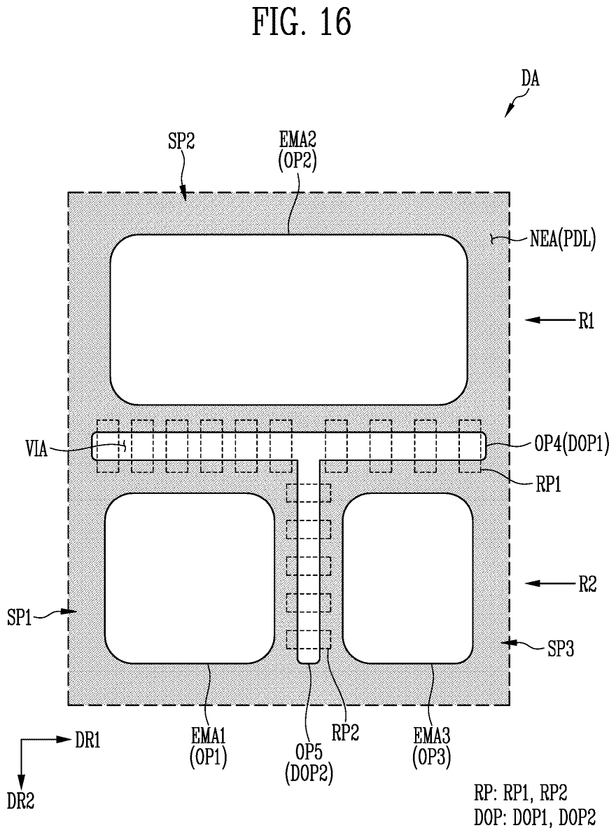

FIG. 16 to FIG. 18 are each a schematic plan view illustrating an area of a display area DA of a display device, according to one or more embodiments of the present disclosure.

In FIG. 16 to FIG. 18, in order to avoid duplicated explanations, the description will be set forth based on the differences from the one or more embodiments described above.

Referring to FIG. 16, the via layer VIA may include the first recessed pattern RP1 and the second recessed pattern RP2 positioned in the non-emission area NEA between adjacent sub-pixels. The pixel defining layer PDL may be positioned in the non-emission area NEA to define the first to third emission areas EMA1 to EMA3.

The pixel defining layer PDL may include the fourth opening OP4 (or the first dummy opening DOP1) and the fifth opening OP5 (or the second dummy opening DOP2) positioned in the non-emission area NEA between adjacent sub-pixels. The fourth opening OP4 may extend in the first direction DR1 and intersect (overlap) the first recessed patterns RP1 of the via layer VIA. The fifth opening OP5 may extend in the second direction DR2 and intersect (overlap) the second recessed patterns PR2 of the via layer VIA. In one or more embodiments, the fourth opening OP4 and the fifth opening OP5 may be connected to form a “T” shape in a plan view.

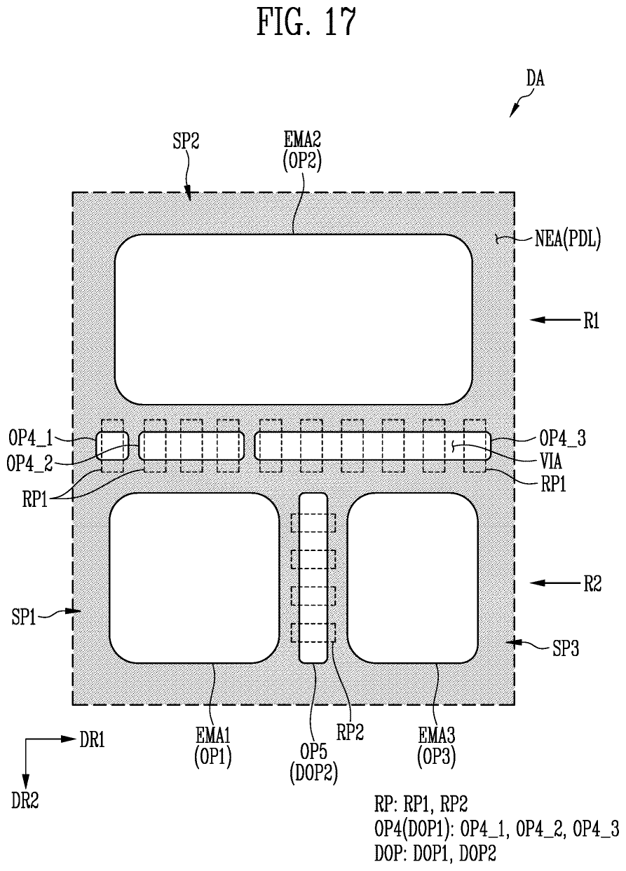

Referring to FIG. 17, the pixel defining layer PDL may include the first dummy opening DOP1 (or the fourth opening OP4) and the second dummy opening DOP2 (or the fifth opening OP5) positioned in an area of the non-emission area NEA between adjacent sub-pixels. The first dummy opening DOP1 and the second dummy opening DOP2 may each extend in a different direction.

In one or more embodiments, the first dummy opening DOP1 may include a 1-1 sub-dummy opening OP4_1, a 1-2 sub-dummy opening OP4_2, and a 1-3 sub-dummy opening OP4_3. The 1-1 sub-dummy opening OP4_1, the 1-2 sub-dummy opening OP4_2, and the 1-3 sub-dummy opening OP4_3 are spaced and/or apart (e.g., spaced apart or separated) from each other and extend in the first direction DR1. The 1-1 sub-dummy opening OP4_1 may intersect (overlap) one first recessed pattern RP1 of the via layer VIA. Each of the 1-2 sub-dummy opening OP4_2 and the 1-3 sub-dummy opening OP4_3 may intersect (overlap) a plurality of first recessed patterns RP1 of the via layer VIA.

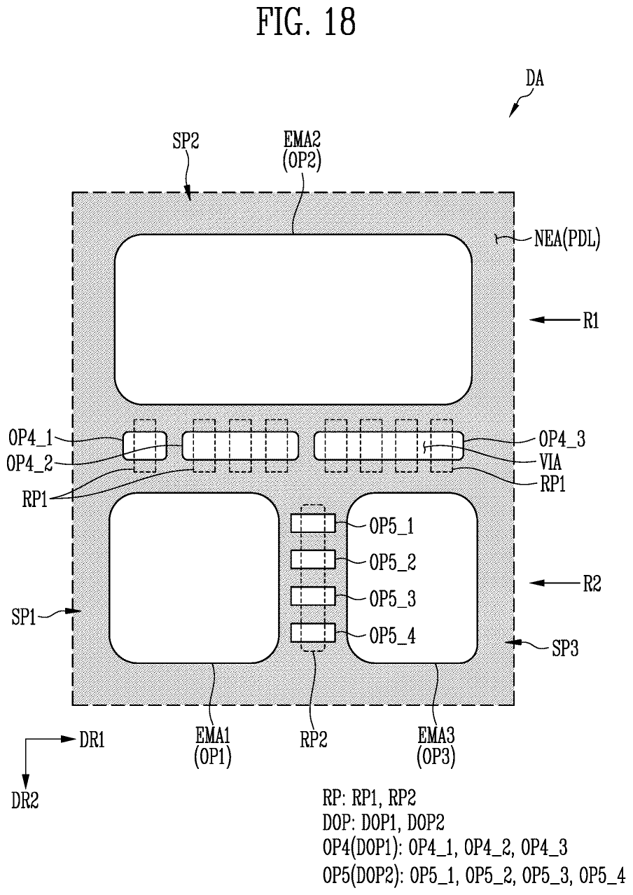

Referring to FIG. 18, the via layer VIA may include the first recessed pattern RP1 and the second recessed pattern RP2 positioned in an area of the non-emission area NEA between adjacent sub-pixels.

The first recessed pattern RP1 of the via layer VIA may extent in the second direction DR2, and a plurality thereof may be provided. Each of the plurality of first recessed patterns RP1 may intersect (overlap) the corresponding sub-dummy opening of the 1-1 to 1-3 sub-dummy openings OP4_1 to OP4_3 of the pixel defining layer PDL. The second recessed pattern RP2 of the via layer VIA may extend in the second direction DR2 and be provided in the form of a line between the first emission area EMA1 and the third emission area EMA3 (or in an area of the non-emission area NEA between the first sub-pixel SP1 and the third sub-pixel SP3).

The pixel defining layer PDL may include the second dummy opening DOP2 (or the fifth opening OP5) positioned in an area of the non-emission area NEA between the first sub-pixel SP1 and the third sub-pixel SP3. The second dummy opening DOP2 may include a plurality of second sub-dummy openings extending in the first direction DR1. For example, the second dummy opening DOP2 may extend in the first direction DR1 and include a 2-1 sub-dummy opening OP5_1, a 2-2 sub-dummy opening OP5_2, a 2-3 sub-dummy opening OP5_3, and a 2-4 sub-dummy opening OP5_4 that are arranged along the second direction DR2.

The 2-1 sub-dummy opening OP5_1, the 2-2 sub-dummy opening OP5_2, the 2-3 sub-dummy opening OP5_3, and the 2-4 sub-dummy opening OP5_4 may intersect (overlap) the second recessed pattern RP2 of the via layer VIA provided in the form of a line. The 2-1 sub-dummy opening OP5_1, the 2-2 sub-dummy opening OP5_2, the 2-3 sub-dummy opening OP5_3, and the 2-4 sub-dummy opening OP5_4 may extend in substantially the same direction as the first dummy opening DOP1.

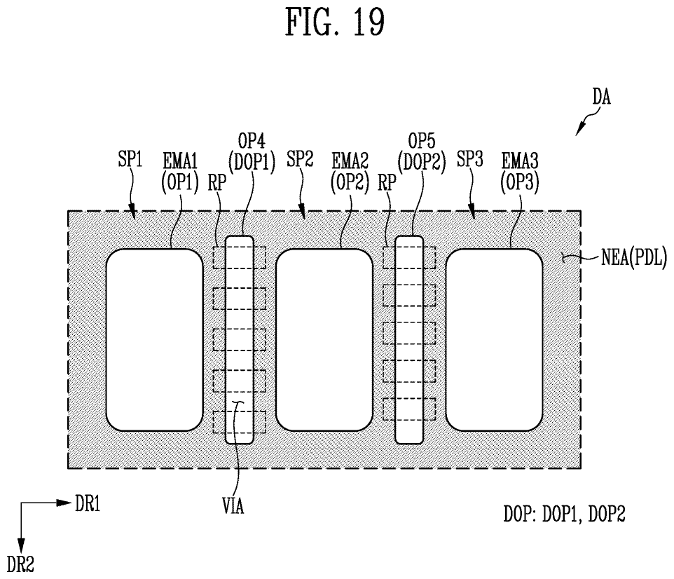

FIG. 19 is a schematic plan view illustrating an area of the display area DA of the display device, according to one or more embodiments of the present disclosure.

In FIG. 19, in order to avoid duplicated explanations, the description will be set forth based on the differences from the one or more embodiments described above.

Referring to FIG. 19, the first sub-pixel SP1, the second sub-pixel SP2, and the third sub-pixel SP3 that are arranged along the first direction DR1 may be arranged in the display area DA. The first to third sub-pixels SP1 to SP3 may be positioned in substantially the same pixel row.

In an area of the non-emission area NEA between adjacent sub-pixels, the recessed patterns RP of the via layer VIA may be positioned. For example, the recessed patterns RP of the via layer VIA may be positioned in an area of the non-emission area NEA between the first sub-pixel SP1 and the second sub-pixel SP2 and in an area of the non-emission area NEA between the second sub-pixel SP2 and the third sub-pixel SP3.

The pixel defining layer PDL may be provided in the non-emission area NEA between adjacent sub-pixels. The pixel defining layer PDL may include the first opening OP1 corresponding to the first emission area EMA, the second opening OP2 corresponding to the second emission area EMA2, and the third opening OP3 corresponding to the third emission area EMA3.

The pixel defining layer PDL may include dummy openings DOP positioned in an area of the non-emission area NEA between adjacent sub-pixels. For example, the pixel defining layer PDL may include the first dummy opening DOP1 (or the fourth opening OP4) positioned in an area of the non-emission area NEA between the first sub-pixel SP1 and the second sub-pixel SP2 and the second dummy opening DOP2 (or the fifth opening OP5) positioned in an area of the non-emission area NEA between the second sub-pixel SP2 and the third sub-pixel SP3. Each of the first and second dummy openings DOP1, DOP2 may expose a portion of the via layer VIA.

In one or more embodiments, the first dummy opening DOP1 and the second dummy opening DOP2 may extend in the second direction DR2 in a plan view. Each of the first and second dummy openings DOP1, DOP2 may intersect (overlap) the recessed patterns RP of the via layer VIA. In such embodiments, both sides (e.g., the first ends ED1 at opposing sides) of the pixel defining layer PDL with the first dummy openings DOP1 interposed therebetween and both sides (e.g., the second ends ED2 at opposing sides) of the pixel defining layer PDL with second dummy openings DOP2 interposed therebetween may be arranged on the corresponding recessed patterns RP to contact the recessed patterns RP. Accordingly, a step inflection point may occur at a point of contact between the recessed patterns RP and the ends of both sides (e.g., the first and second ends ED1 and ED2 at opposing sides) of the pixel defining layer PDL to cause an increase in the tilt (angle) of both sides (e.g., the first and second ends ED1 and ED2 at opposing sides) of the pixel defining layer PDL with the dummy opening DOP interposed therebetween. For example, the first dummy opening DOP1 and the second dummy opening DOP2 may extend in the second direction DR2 and intersect (overlap) with the recessed patterns RP of the via layer VIA. In such embodiments, the ends ED1 and ED2 of both sides of the pixel defining layer PDL, with the dummy openings DOP1 and DOP2 interposed between them, may be arranged on the corresponding recessed patterns RP. This arrangement may create a step inflection point, increasing the tilt of the pixel defining layer PDL.

A display device according to an embodiment is applicable to various types of electronic devices. In an embodiment, an electronic device includes the above-described display device and may further include other modules or devices having additional functions in addition to the display device.

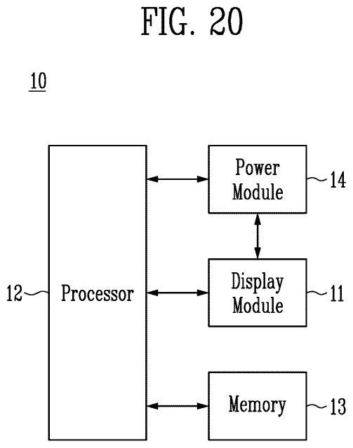

FIG. 20 is a block diagram of an electronic device according to an embodiment. Referring to FIG. 20, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

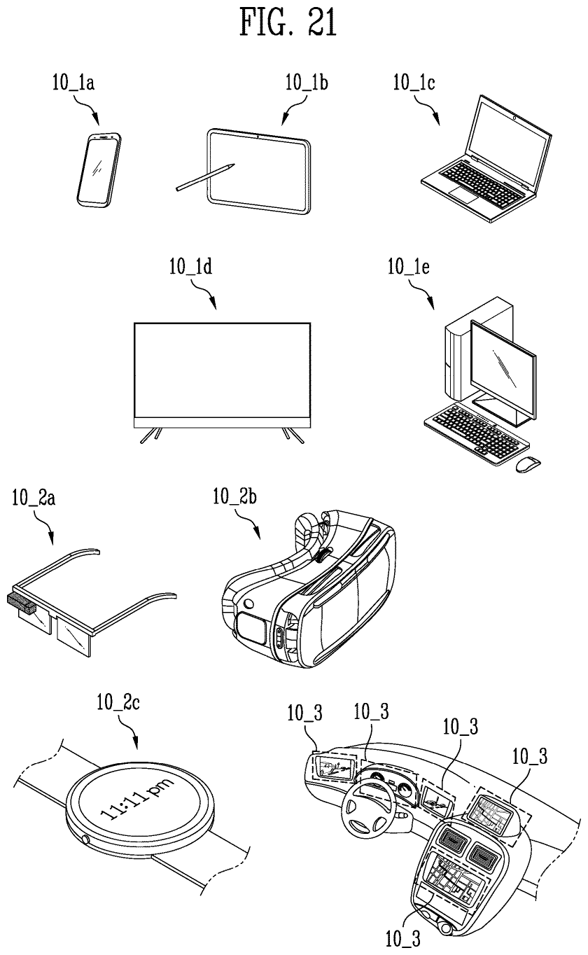

FIG. 21 shows schematic views of various embodiments of an electronic device.

Referring to FIG. 21, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light emitting device, the electronic apparatus, a manufacturing device thereof, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a plurality of sub-pixels on the substrate;
a via layer on the substrate and defining a recessed pattern recessed in a direction toward the substrate; and
a pixel defining layer defining an emission area and on the via layer in a non-emission area around the emission area,
wherein the pixel defining layer defines a light-emitting opening corresponding to the emission area and a dummy opening exposing a portion of the via layer in the non-emission area, and
wherein, in a plan view, the recessed pattern of the via layer and the dummy opening of the pixel defining layer overlap each other.

2. The display device of claim 1, wherein the sub-pixels comprise a first sub-pixel emitting light of a first color, a second sub-pixel emitting light of a second color, and a third sub-pixel emitting light of a third color, and
wherein the emission area comprises a first emission area defining the first sub-pixel, a second emission area defining the second sub-pixel, and a third emission area defining the third sub-pixel.

3. The display device of claim 2, wherein the dummy opening comprises:
a first dummy opening extending in a first direction in the non-emission area between the first sub-pixel and the second sub-pixel and in the non-emission area between the second sub-pixel and the third sub-pixel; and
a second dummy opening extending in a second direction intersecting the first direction in the non-emission area between the first sub-pixel and the third sub-pixel.

4. The display device of claim 3, wherein the recessed pattern comprises:
a first recessed pattern extending in the second direction and overlapping the first dummy opening; and
a second recessed pattern extending in the first direction and overlapping the second dummy opening.

5. The display device of claim 4, wherein the first dummy opening and the second dummy opening are spaced from each other.

6. The display device of claim 4, wherein the first dummy opening and the second dummy opening are connected.

7. The display device of claim 4, wherein:
a plurality of first ends of the pixel defining layer at opposing sides of the pixel defining layer define the first dummy opening therebetween and are on the first recessed pattern; and
a plurality of second ends of the pixel defining layer at opposing sides of the pixel defining layer define the second dummy opening therebetween and are on the second recessed pattern.

8. The display device of claim 7, wherein a boundary point between an upper surface of the via layer and the recessed pattern is covered by the pixel defining layer.

9. The display device of claim 7, wherein the first ends of the pixel defining layer contact the first recessed pattern to define a first trench, and
wherein the second ends of the pixel defining layer contact the second recessed pattern to define a second trench.

10. The display device of claim 9, further comprising:
an anode electrode between the via layer of each of the sub-pixels and the pixel defining layer and exposed by the light-emitting opening of the pixel defining layer;
an emission structure on the anode electrode and the pixel defining layer; and
a cathode electrode on the emission structure,
wherein the emission structure comprises:
a first emission unit on the anode electrode and the pixel defining layer and to emit light;
an intermediate layer on the first emission unit; and
a second emission unit on the intermediate layer and to emit light, and
wherein the first emission unit and the intermediate layer are disconnected at each of the first and second trenches, and the second emission unit is not disconnected on the first and second trenches.

11. The display device of claim 10, wherein the first trench defines a first void defined by the first recessed pattern, the first ends of the pixel defining layer, the first emission unit, the intermediate layer, and the second emission unit, and
wherein the second trench defines a second void defined by the second recessed pattern, the second ends, the first emission unit, the intermediate layer, and the second emission unit.

12. The display device of claim 4, wherein the first recessed pattern comprises a plurality of first recessed patterns arranged along the first direction,
wherein the second recessed pattern comprises a plurality of second recessed patterns arranged along the second direction,
wherein each of the plurality of first recessed patterns overlaps the first dummy opening, and
wherein each of the plurality of second recessed patterns overlaps the second dummy opening.

13. The display device of claim 4, wherein the first dummy opening comprises a plurality of first sub-dummy openings which are spaced from each other, and
wherein at least one of the plurality of first sub-dummy openings overlaps one of the first recessed patterns.

14. The display device of claim 2,
wherein the dummy opening comprises:
a first dummy opening extending in a first direction in the non-emission area between the first sub-pixel and the second sub-pixel and in the non-emission area between the second sub-pixel and the third sub-pixel; and
a second dummy opening extending in the first direction in the non-emission area between the first sub-pixel and the third sub-pixel, and
wherein the second dummy opening comprises a plurality of second sub-dummy openings extending in the first direction and arranged along a second direction intersecting the first direction.

15. The display device of claim 14,
wherein the recessed pattern comprises:
a first recessed pattern extending in the second direction and overlapping the first dummy opening; and
a second recessed pattern extending in the second direction and overlapping the plurality of second sub-dummy openings, and
wherein the second recessed pattern has the shape of a line.

16. The display device of claim 2,
wherein the dummy opening comprises:
a first dummy opening extending in a second direction in the non-emission area between the first sub-pixel and the second sub-pixel; and
a second dummy opening extending in the second direction in the non-emission area between the second sub-pixel and the third sub-pixel, and
wherein the recessed pattern extends in a first direction intersecting the second direction and overlaps each of the first and second dummy openings.

17. A display device comprising:
a substrate;
a first sub-pixel, a second sub-pixel, and a third sub-pixel, the first, second, and third sub-pixels being on the substrate;
a via layer on the substrate and defining a recessed pattern recessed in a direction toward the substrate; and
a pixel defining layer on the via layer in a non-emission area and defining a first emission area of the first sub-pixel, a second emission area of the second sub-pixel, and a third emission area of the third sub-pixel,
wherein the pixel defining layer defines a first opening corresponding to the first emission area, a second opening corresponding to the second emission area, a third opening corresponding to the third emission area, and a dummy opening exposing a portion of the via layer in the non-emission area,
wherein, in a plan view, the recessed pattern of the via layer and the dummy opening of the pixel defining layer overlap each other.

18. An electronic device comprising:
a display device comprising:
a substrate;
sub-pixels on the substrate;
a via layer on the substrate and defining a recessed pattern recessed in a direction toward the substrate; and
a pixel defining layer defining an emission area and on the via layer in a non-emission area around the emission area,
wherein the pixel defining layer defines a light-emitting opening corresponding to the emission area and a dummy opening exposing a portion of the via layer in the non-emission area, and
wherein, in a plan view, the recessed pattern of the via layer and the dummy opening of the pixel defining layer overlap each other.

19. The electronic device of claim 18, wherein the sub-pixels comprise a first sub-pixel emitting light of a first color, a second sub-pixel emitting light of a second color, and a third sub-pixel emitting light of a third color, and
wherein the emission area comprises a first emission area defining the first sub-pixel, a second emission area defining the second sub-pixel, and a third emission area defining the third sub-pixel.

20. The electronic device of claim 19,
wherein the dummy opening comprises:
a first dummy opening extending in a first direction in the non-emission area between the first sub-pixel and the second sub-pixel and in the non-emission area between the second sub-pixel and the third sub-pixel; and
a second dummy opening extending in a second direction intersecting the first direction in the non-emission area between the first sub-pixel and the third sub-pixel,
wherein the recessed pattern comprises:
a first recessed pattern extending in the second direction and overlapping the first dummy opening; and
a second recessed pattern extending in the first direction and overlapping the second dummy opening, and
wherein the first dummy opening and the second dummy opening are spaced from each other.
